(19) United States
(12) Patent Application Publication
(10) Pub. No.: US 2025/0342789 A1
(43) Pub. Date: Nov. 6, 2025

(54) GAMMA AMPLIFIER OPERATING IN SAMPLE PERIOD AND HOLD PERIOD FOR OFFSET CANCELLATION, GAMMA VOLTAGE GENERATOR INCLUDING THE SAME, AND DISPLAY DRIVER INTEGRATED CIRCUIT INCLUDING THE SAME

(71) Applicant: SAMSUNG ELECTRONICS CO., LTD., Suwon-si (KR)

(72) Inventors: Jiyong Jeong, Suwon-si (KR); Nahoo Lee, Suwon-si (KR); Donghan Lee, Suwon-si (KR); Hyunsik Lee, Suwon-si (KR); Jeonghyun Ju, Suwon-si (KR)

(73) Assignee: SAMSUNG ELECTRONICS CO., LTD., Suwon-si (KR)

(21) Appl. No.: 19/189,720

(22) Filed: Apr. 25, 2025

(30) Foreign Application Priority Data
May 2, 2024 (KR) 10-2024-0058678
Sep. 9, 2024 (KR) 10-2024-0122577

(51) Int. Cl. G09G 3/20

(52) U.S. Cl. CPC G09G 3/2007; G09G 3/2096; G09G 2330/021; G09G 2330/028

(57) ABSTRACT

A gamma amplifier includes a first gamma amplification stage that amplifies a first voltage, a sample driving stage that amplifies a second voltage that is output from the first gamma amplification stage, during a first sample period in which a first offset of the gamma amplifier is sampled, a hold driving stage that amplifies a third voltage that is output from the first gamma amplification stage, during a first hold period in which the first offset is canceled, and a switching stage that connects the first gamma amplification stage to one stage of the hold driving stage and the sample driving stage. The sample driving stage consumes less power than the hold driving stage.

### CROSS-REFERENCE TO RELATED APPLICATION

This application is based on and claims priority under 35 USC § 119 to Korean Patent Application No. 10-2024-0058678, filed on May 2, 2024 and to Korean Patent Application No. 10-2024-0122577, filed on Sep. 9, 2024, in the Korean Intellectual Property Office, the disclosures of each of which being incorporated by reference herein in their entireties.

### BACKGROUND

The present disclosure relates to a gamma amplifier that outputs a voltage to output an image on a display panel, a gamma voltage generator including the same, and a display driver integrated circuit including the same.

As screen sizes and resolutions of display devices have gradually increased, a plurality of display driver integrated circuits have been used to drive display panels. In addition, research has been actively conducted to perform a precise operation of each display driver integrated circuit and to minimize deviation in driving characteristics between a plurality of display driver integrated circuits.

As part of the research, there has been proposed a structure of gamma amplifiers that perform an auto-zero operation to cancel offsets of gamma amplifiers caused by process issues of gamma amplifiers of gamma voltage generators included in display driver integrated circuits. However, the efficiency of gamma amplifiers performing auto-zero operations has fallen.

### SUMMARY

It is an aspect to provide a gamma amplifier capable of improving the stability of an auto-zero operation, while increasing the efficiency of power usage, a gamma voltage generator including the same, and a display driver integrated circuit including the same.

According to an aspect of one or more embodiments, there is provided a gamma amplifier comprising a first gamma amplification stage configured to amplify a first voltage; a sample driving stage configured to amplify a second voltage that is output from the first gamma amplification stage, during a first sample period in which a first offset of the gamma amplifier is sampled; a hold driving stage configured to amplify a third voltage that is output from the first gamma amplification stage, during a first hold period in which the first offset is canceled; and a switching stage configured to connect the first gamma amplification stage to one stage of the hold driving stage and the sample driving stage. The sample driving stage consumes less power than the hold driving stage.

According to an aspect of one or more embodiments, wherein the first sample period and the first hold period are periodically and alternately arranged.

According to an aspect of one or more embodiments, there is provided the gamma amplifier further comprising: an input terminal, wherein the first voltage and the fourth voltage are input to the first gamma amplification stage and the second gamma amplification stage, respectively, through the input terminal. According to another aspect of one or more embodiments, there is provided a gamma amplifier comprising a first gamma amplification stage configured to amplify a first voltage; a hold driving stage configured to amplify a second voltage that is output from the first gamma amplification stage, during a first hold period in which a first offset of the gamma amplifier is canceled; and a switching stage configured to connect the first gamma amplification stage to the hold driving stage in the first hold period and to connect the first gamma amplification stage to a first sampling node during a first sample period in which the first offset is sampled.

According to another aspect of one or more embodiments, wherein the first sample period corresponds to the second hold period, and the first hold period corresponds to the second sample period.

According to another aspect of one or more embodiments, there is provided the gamma amplifier comprising: an input terminal; an output terminal; a first gamma amplification stage configured to amplify a first voltage input to the input terminal; and an output connection stage configured to control, based on the first gamma amplification stage operating on low power, a first connection for a sampling operation for a first offset of the gamma amplifier, or a second connection for amplifying a second voltage that is output from the first gamma amplification stage and for outputting, through the output terminal, the second voltage that is amplified, based on an operation period of the first gamma amplification stage.

According to another aspect of one or more embodiments, wherein the operation period of the first gamma amplification stage includes a sample period in which the sampling operation for the first offset is performed, and a hold period in which the first offset is canceled and the second voltage is output.

According to another aspect of one or more embodiments, there is provided the gamma amplifier further comprising: a second gamma amplification stage configured to amplify a third voltage input to the input terminal, wherein the output connection stage is configured to control, based on the second gamma amplification stage operating on low power, a third connection for a sampling operation for a second offset of the gamma amplifier, or a fourth connection for amplifying a fourth voltage that is output from the second gamma amplification stage and for outputting, through the output terminal, the fourth voltage that is amplified, based on an operation period of the second gamma amplification stage.

According to another aspect of one or more embodiments, wherein the output connection stage is further configured to control the first connection and the fourth connection together and to control the second connection and the third connection together. According to yet another aspect of one or more embodiments, there is provided a gamma amplifier comprising an input terminal; an output terminal; a first gamma amplification stage configured to amplify a first voltage input to the input terminal; and an output connection stage configured to control, based on the first gamma amplification stage operating on low power, a first connection for a sampling operation for a first offset of the gamma amplifier, or a second connection for amplifying a second voltage that is output from the first gamma amplification stage and for outputting, through the output terminal, the second voltage that is amplified, based on an operation period of the first gamma amplification stage.

According to still yet another aspect of one or more embodiments, there is provided a display driver integrated circuit comprising a gate driver integrated circuit configured to control a plurality of gate lines connected to a display panel; a gamma voltage generator configured to generate a plurality of gamma voltages; and a source driver integrated circuit configured to control a plurality of data lines connected to the display panel, based on the plurality of gamma voltages and based on data. The gamma voltage generator includes a plurality of gamma amplifiers configured to sample an offset on a low power basis during a sample period and to generate a gamma voltage, based on the offset sampled during the sample period, during a hold period.

According to still yet another aspect of one or more embodiments, wherein the sample driving stage consumes less power than the hold driving stage.

According to still yet another aspect of one or more embodiments, The display driver integrated circuit of claim 28, wherein: the plurality of second gamma amplifiers are arranged to generate gamma voltages corresponding to a middle range among the plurality of gamma voltages, and the plurality of first gamma amplifiers are arranged to generate gamma voltages corresponding to remaining ranges other than the middle range among the plurality of gamma voltages.

According to still yet another aspect of one or more embodiments, wherein one of the plurality of gamma amplifiers includes a first gamma amplification stage and a second gamma amplification stage configured to perform mutual ping-pong-based operations.

### BRIEF DESCRIPTION OF THE DRAWINGS

Various embodiments will be more clearly understood from the following detailed description taken in conjunction with the accompanying drawings, in which:

FIG. 1 is a block diagram schematically illustrating a display device according to an embodiment;

FIG. 2 is a block diagram illustrating a gamma voltage generator of FIG. 1, according to an embodiment;

FIG. 3 is a diagram illustrating a portion of the gamma voltage generator of FIG. 2, according to an embodiment;

FIG. 4 is a flowchart illustrating operations of a gamma amplifier according to an embodiment;

FIG. 5A is a block diagram schematically illustrating a gamma voltage generator according to an embodiment, FIG. 5B is a diagram illustrating operations of an A-gamma amplification stage and a B-gamma amplification stage of FIG. 5A, according to an embodiment, FIG. 5C is a circuit diagram in a first sample period of a first amplification circuit including the A-gamma amplification stage of FIG. 5A, according to an embodiment, and FIG. 5D is a circuit diagram in a first hold period of the first amplification circuit including the A-gamma amplification stage of FIG. 5A, according to an embodiment;

FIG. 6 is a block diagram illustrating a gamma amplifier according to an embodiment;

FIGS. 7A and 7B are diagrams illustrating operations of the gamma amplifier of FIG. 6, according to an embodiment;

FIG. 8 is a circuit diagram illustrating a gamma amplifier according to an embodiment;

FIGS. 9A and 9B are diagrams illustrating operations of the gamma amplifier of FIG. 8, according to an embodiment;

FIG. 10 is a block diagram illustrating a gamma amplifier according to an embodiment;

FIGS. 11A and 11B are diagrams illustrating operations of the gamma amplifier of FIG. 10, according to an embodiment;

FIG. 12 is a circuit diagram illustrating a gamma amplifier according to an embodiment;

FIGS. 13A and 13B are diagrams illustrating operations of the gamma amplifier of FIG. 12, according to an embodiment;

FIG. 14 is a block diagram illustrating a gamma voltage generator according to an embodiment;

FIG. 15 is a diagram illustrating an implementation example of gamma amplifiers included in the gamma voltage generator of FIG. 14, according to an embodiment;

FIG. 16 illustrates an implementation example of a display device according to an embodiment; and

FIG. 17 illustrates an implementation example of a display device according to an embodiment.

### DETAILED DESCRIPTION

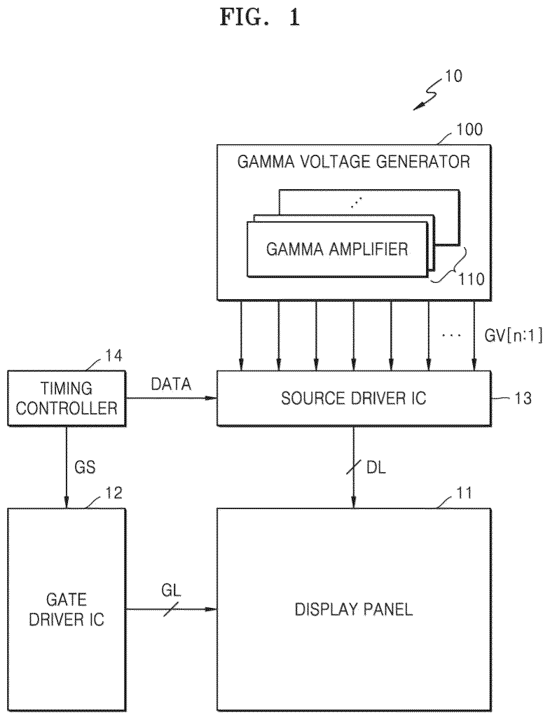

FIG. 1 is a block diagram illustrating a display device 10 according to an embodiment.

Referring to FIG. 1, the display device 10 may include a display panel 11, a gate driver integrated circuit (IC) 12, a source driver IC 13, a timing controller 14, and a gamma voltage generator 100. In an embodiment, the gate driver IC 12, the source driver IC 13, the timing controller 14, and the gamma voltage generator 100 may be included in a display driver integrated circuit. In some embodiments, the gate driver IC may be referred to as a row driver IC and the source driver IC may be referred to as a data driver IC.

The display panel 11 may include a plurality of pixels. The pixels may be arranged side by side in rows and columns. The pixels may be connected to a plurality of source lines SL (or a plurality of data lines) and a plurality of gate lines GL (or a plurality of scan lines). For example, the display panel 11 may include various display panels, such as a liquid crystal display panel, an organic light emitting display panel, an electrophoretic display panel, an electrowetting display panel, etc.

The gate driver IC 12 may be connected to the display panel 11 through the gate lines GL. The gate driver IC 12 may receive a gate signal GS from the timing controller 14 and control voltages of the gate lines GL in response to the received gate signal GS. For example, the gate driver IC 12 may sequentially apply voltages corresponding to the gate signal GS to the gate lines GL in response to the gate signal GS.

The source driver IC 13 may be connected to the display panel 11 via the source lines SL. The source driver IC 13 may receive data DATA from the timing controller 14 and may control voltages of the source lines SL based on the received data DATA. For example, the source driver IC 13 may receive a plurality of gamma voltages GV[n:1] from the gamma voltage generator 100 and control the voltages of the source lines SL based on the data DATA using the received gamma voltages GV[n:1].

The timing controller 14 may receive various control signals, such as the data DATA and synchronization signals, from an external device (e.g., a graphics processing unit (GPU), an application processor, etc.). The timing controller 14 may control various components of the display device 10 so that an image corresponding to the data DATA is output through the display panel 11 in response to a received control signal.

In an embodiment, the gamma voltage generator 100 may efficiently generate the plurality of gamma voltages GV[n:1] having various levels to be used in the source driver IC 13 in terms of power. For example, the gamma voltage generator 100 may include a plurality of gamma amplifiers 110, and the plurality of gamma amplifiers 110 may have a structure that minimizes power consumption in a certain section when the gamma amplifiers 110 perform an amplification operation to generate a gamma voltage.

When a voltage difference between two input terminals (a positive input terminal and a negative input terminal) of the gamma amplifier 110 is 0 (zero), the voltage of the output terminal of the gamma amplifier 110 has to be 0, but in reality, due to an issue in the imperfect manufacturing process, an error equal to an offset may be included in the voltage of the output terminal. Although a plurality of gamma amplifiers 110 are manufactured using a same manufacturing process, offsets of the gamma amplifiers 110 may be different from each other. Accordingly, for an effective operation of the gamma voltage generator 100, it is advantageous to cancel the offsets of the gamma amplifiers 110. To this end, the gamma amplifier 110 may repeatedly sample the offset in a sample period and cancel the offset in a hold period when amplifying the input voltage. Herein, the sample period, as a period during which the voltage amplified by the gamma amplifier 110 is not output externally, may be referred to as a standby period, and the hold period, as a period during which the voltage amplified by the gamma amplifier 110 is output externally, may be referred to as an output period.

In an embodiment, the gamma amplifier 110 may control an internal connection within the gamma amplifier 110 so that power consumption is reduced during the sample period. For example, the gamma amplifier 110 may include a gamma amplification stage that mainly performs an amplification operation, and an output connection stage, and the output connection stage may control a connection to the gamma amplification stage based on an operation period (e.g., a sample period or a hold period) of the gamma amplification stage. As an example, the output connection stage may control the connection to the gamma amplification stage so that the gamma amplification stage may operate on a low power basis during the sample period and may control the connection to the gamma amplification stage so that the gamma amplification stage may operate optimally during the hold period. Herein, the gamma amplification stage in the sample period may be referred to as operating in a sample mode or a low power mode, and the gamma amplification stage in the hold period may be referred to as operating in a hold mode or a normal mode.

In an embodiment, the output connection stage may include a sample driving stage for low power-based amplification operation in the sample period, a hold driving stage for an amplification operation in the hold period, and a switching stage connecting one stage of the sample driving stage or the hold driving stage to the gamma amplification stage based on an operating period. For example, the sample driving stage and the hold driving stage may be connected to the gamma amplification stage to perform a secondary amplification operation. Herein, an amplification gain of the secondary amplification operation of the sample driving stage or the hold driving stage may be less than an amplification gain of a primary amplification operation of the gamma amplification stage. The sample driving stage may be configured to consume less power than the hold driving stage.

In some embodiments, the sample driving stage described above may be omitted in the output connection stage, and the output connection stage may include a hold driving stage for an amplification operation in the hold period and a switching stage connecting the hold driving stage to the gamma amplification stage in the hold period. The gamma amplification stage may be connected to the sampling node in the sample period to sample an offset. That is, in an embodiment, the sample driving stage described above may be omitted in the output connection stage, so that power consumed in the sample driving stage may be further saved. Due to the omission of the sample driving stage, the structure of the gamma amplification stage may vary, and details thereof are described below.

However, the embodiments are not limited to the embodiments of the output connection stage described above and, in some embodiments, the output connection stage may be implemented variously so that power consumption of the gamma amplifier 110 during the sample period is reduced.

In an embodiment, the gamma amplifier 110 may include an output connection stage and first and second gamma amplification stages that perform mutual ping-pong-based operations. As an example, a first sample period of the first gamma amplification stage may correspond to a second hold period of the second gamma amplification stage, and a first hold period of the first gamma amplification stage may correspond to a second sample period of the second gamma amplification stage. The output connection stage may control the connection of the first and second gamma amplification stages together so that the first gamma amplification stage may operate on a low power basis in the first sample period and the second gamma amplification stage may operate optimally in the second hold period and may control the connection of the first and second gamma amplification stages together so that the first gamma amplification stage may operate optimally in the first hold period and the second gamma amplification stage may operate on a low power basis in the second sample period.

In an embodiment, the gamma voltage generator 100 may further include a control circuit that generates a control signal that is based on the operation of an output connection stage included in each of the gamma amplifiers 110. In some embodiments, the control circuit may be included in the timing controller 14 or implemented as a separate logic circuit from the gamma voltage generator 100. In some embodiments, the control circuit may be implemented as software or firmware executed by a processor.

The gamma amplifiers 110 that perform an effective amplification operation by removing an offset may perform an operation on a low power basis in the sample period in which an offset is sampled, thereby saving power in the sample period. The gamma amplifiers 110 may adaptively increase power consumption in the hold period compared to the sample period to improve the stability of the amplification operation, thereby increasing the efficiency of the gamma voltage generator 100 with respect to power consumption.

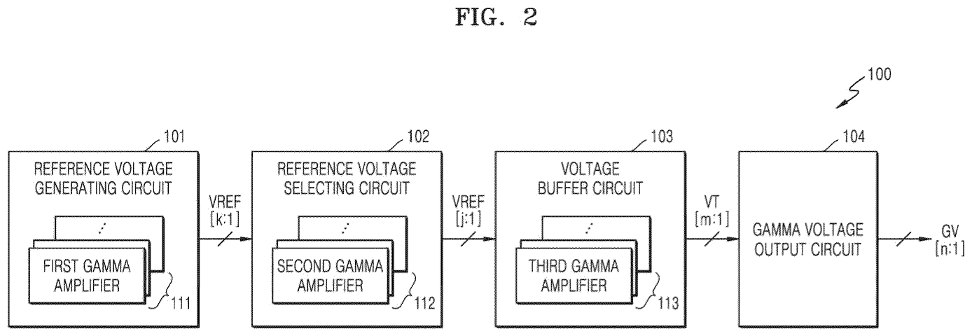

FIG. 2 is a block diagram illustrating the gamma voltage generator 100 of FIG. 1, according to an embodiment.

Referring to FIG. 2, the gamma voltage generator 100 may include a reference voltage generating circuit 101, a reference voltage selecting circuit 102, a voltage buffer circuit 103, and a gamma voltage output circuit 104.

In an embodiment, the reference voltage generating circuit 101 may generate a plurality of first reference voltages VREF[k:1] used in the gamma voltage generator 100. In an embodiment, the reference voltage generating circuit 101 may include at least one resistor string in which a plurality of resistors are connected in series and a plurality of first gamma amplifiers 111. The first gamma amplifiers 111 are included in the gamma amplifiers 110 of FIG. 1, and the embodiments of the gamma amplifier 110 described above may be applied thereto. The reference voltage generating circuit 101 may adjust the levels of voltages output from the first gamma amplifiers 111 through at least one resistor string and output the same as the first reference voltages VREF[k:1].

In an embodiment, the reference voltage selecting circuit 102 may generate a plurality of second reference voltages VREF[j:1] used in the gamma voltage generator 100 based on the first reference voltages VREF[k:1] received from the reference voltage generating circuit 101. For example, in an embodiment, the second reference voltages VREF[j:1] may include a greater number of subdivided reference voltages than the first reference voltages VREF[k:1]. In an embodiment, the reference voltage selecting circuit 102 may include a plurality of multiplexers for selecting a portion of the first reference voltages VREF[k:1], at least one resistor string for generating the second reference voltages VREF[j:1] based on the first reference voltages selected by the multiplexers, and a plurality of second gamma amplifiers 112. The second gamma amplifiers 112 are included in the gamma amplifiers 110 of FIG. 1, and the embodiments of the gamma amplifier 110 described above may be applied thereto. The reference voltage selecting circuit 102 may output the second reference voltages VREF[j:1] based on the first reference voltages VREF[k:1].

In an embodiment, the voltage buffer circuit 103 may generate a plurality of tap voltages VT[m:1] based on the second reference voltages VREF[j:1] received from the reference voltage selecting circuit 102. In an embodiment, the voltage buffer circuit 103 may include a plurality of third gamma amplifiers 113. For example, the third gamma amplifiers 113 may output a tap voltage using one of the second reference voltages VREF[j:1]. The third gamma amplifiers 113 are included in the gamma amplifiers 110 of FIG. 1, and the embodiments of the gamma amplifier 110 described above may be applied thereto.

In an embodiment, the gamma voltage output circuit 104 may output a plurality of gamma voltages GV[n:1] using the tap voltages VT[m:1]. In an embodiment, the gamma voltage output circuit 104 may include at least one resistor string in which a plurality of resistors are connected in series. The tap voltages VT[m:1] may be applied to at least one resistor string so that a plurality of gamma voltages GV[n:1] may be output through at least one resistor string.

The gamma voltage generator 100 may generate different gamma voltages for each channel connected to the source driver IC 13 (see FIG. 1). For example, when the display panel 11 is configured to display red, green, and blue (RGB) colors, the gamma voltage generator 100 may generate a plurality of R-gamma voltages corresponding to an R-channel, a plurality of G-gamma voltages corresponding to a G-channel, and a plurality of B-gamma voltages corresponding to a B-channel. However, for convenience of description, various embodiments are described in which the gamma voltage generator 100 generate a plurality of gamma voltages corresponding to one channel. However, it will be clearly understood that the embodiments are not limited thereto.

In an embodiment, a same implementation method may be applied to the first to third gamma amplifiers 111, 112, and 113. As an example, the first to third gamma amplifiers 111, 112, and 113 may be implemented to include the sample driving stage described above with reference to FIG. 1. As another example, the first to third gamma amplifiers 111, 112, and 113 may be implemented such that the sample driving stage described above with reference to FIG. 1 is omitted.

In an embodiment, an implementation method of a portion of the first to third gamma amplifiers 111, 112, and 113 may be different from an implementation method of the others of the first to third gamma amplifiers 111, 112, and 113. For example, a portion of the first to third gamma amplifiers 111, 112, and 113 may be implemented to include the sample driving stage described above with reference to FIG. 1, and a remaining portion of the first to third gamma amplifiers 111, 112, and 113 may be implemented to omit the sample driving stage described above with reference to FIG. 1.

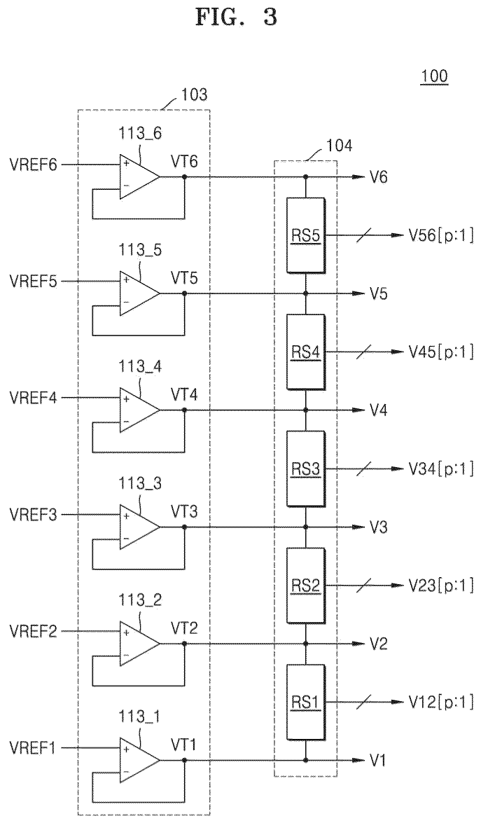

FIG. 3 is a diagram illustrating a portion of the gamma voltage generator 100 of FIG. 2, according to an embodiment. FIG. 3 illustrates the arrangement and operation of third gamma amplifiers 113_1 to 113_6 according to an embodiment.

Referring to FIG. 3, the gamma voltage generator 100 (see FIG. 2) may include a voltage buffer circuit 103 and a gamma voltage output circuit 104.

In an embodiment, the voltage buffer circuit 103 may include the third gamma amplifiers 113_1 to 113_6. The third gamma amplifiers 113_1 to 113_6 may generate a plurality of tap voltages VT1 to VT6 based on a plurality of second reference voltages VREF1 to VREF6. For example, the third gamma amplifier 113_1 may receive a reference voltage VREF1 through a positive input terminal (or a non-inverting input terminal) and output a tap voltage VT1 corresponding to the reference voltage VREF1. The first gamma amplifier 113_1 may receive the tap voltage VT1 through a negative input terminal (or an inverting input terminal) to maintain the level of the tap voltage VT1. In a similar manner, the other third gamma amplifiers 113_2 to 113_6 may output the tap voltage VT2 to the tap voltage VT6 respectively corresponding to the reference voltage VREF2 to the reference voltage VREF6.

In an embodiment, the tap voltage VT1 may be output as a gamma voltage V1. The tap voltage VT2 may be output as the gamma voltage V2. The tap voltage VT3 may be output as the gamma voltage V3. The tap voltage VT4 may be output as the gamma voltage V4. The tap voltage VT5 may be output as the gamma voltage V5. The tap voltage VT6 may be output as the gamma voltage V6.

In an embodiment, the gamma voltage output circuit 104 may include a plurality of resistor strings RS1 to RS5. Each of the resistor strings RS1 to RS5 may include a plurality of resistors connected in series between two nodes among the output nodes of the third gamma amplifiers 113_1 to 113_6. A plurality of gamma voltages V12[p:1] to V56[p:1] may be output by the plurality of resistors of the resistor strings RS1 to RS5.

As an example, the first resistor string RS1 may be connected between a node at which the tap voltage VT1 is output and a node at which the tap voltage VT2 is output. The level of each of the first gamma voltages V12[p:1] may be a level between the tap voltage VT1 and the tap voltage VT2 and may be determined by a resistance value ratio of the resistors included in the first resistor string RS1. The second resistor string RS2 may be connected between the node at which the tap voltage VT2 is output and a node at which the tap voltage VT3 is output. The level of each of the second gamma voltages V23[p:1] may be a level between the tap voltage VT2 and the tap voltage VT3 and may be determined by a resistance value ratio of the resistors included in the second resistor string RS2. The third resistor string RS3 may be connected between the node at which the tap voltage VT3 is output and a node at which the tap voltage VT4 is output. The level of each of the third gamma voltages V34[p:1] may be a level between the tap voltage VT3 and the tap voltage VT4 and may be determined by a resistance value ratio of the resistors included in the third resistor string RS3. The fourth resistor string RS4 may be connected between the node at which the tap voltage VT4 is output and a node at which the tap voltage VT5 is output. The level of each of the fourth gamma voltages V45[p:1] may be a level between the tap voltage VT4 and the tap voltage VT5 and may be determined by a resistance value ratio of the resistors included in the fourth resistor string RS4. The fifth resistor string RS5 may be connected between the node at which the tap voltage VT5 is output and a node at which the tap voltage VT6 is output. The level of each of the fifth gamma voltages V56[p:1] may be a level between the tap voltage VT5 and the tap voltage VT6 and may be determined by a resistance value ratio of the resistors included in the fifth resistor string RS5.

In an embodiment, the gamma voltages V12[p:1] to V56[p:1] generated by the gamma voltage output circuit 104 may be used by the source driver IC 13 of FIG. 1.

The embodiments of the gamma amplifier described above with reference to FIGS. 1 and 2 may be applied to the third gamma amplifiers 113_1 to 113_6 of the voltage buffer circuit 103. The embodiment illustrated in FIG. 3 is merely presented as an example, and it will be fully understood that embodiments are not limited thereto.

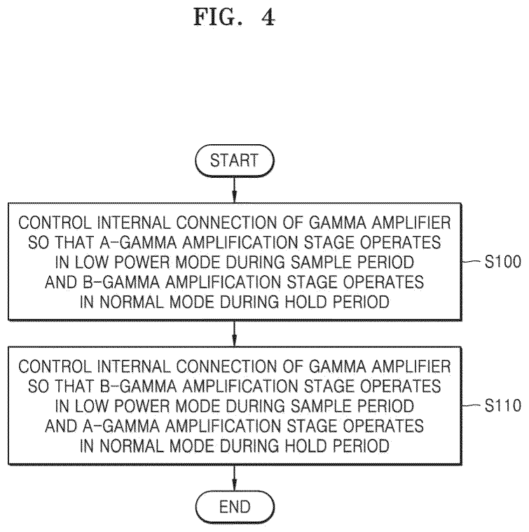

FIG. 4 is a flowchart illustrating the operation of a gamma amplifier according to an embodiment. In FIG. 4, it is assumed that the gamma amplifier includes an A-gamma amplification stage and a B-gamma amplification stage performing mutual ping-pong-based operations. Herein, the A-gamma amplification stage may be referred to as a first gamma amplification stage, and the B-gamma amplification stage may be referred to as a second gamma amplification stage.

Referring to FIG. 4, in operation S100, the internal connection of the gamma amplifier may be controlled so that the A-gamma amplification stage operates in the low power mode during the sample period and the B-gamma amplification stage operates in the normal mode during the hold period. For example, during the sample period, the A-gamma amplification stage may be connected to a stage or node that consumes low power to sample a first offset of the gamma amplifier. Herein, the first offset may be an offset associated with the A-gamma amplification stage. During the hold period corresponding to the sample period of the A-gamma amplification stage, the B-gamma amplification stage may be connected to a stage that outputs the voltage amplified in the B-gamma amplification stage externally and a second offset of the gamma amplifier may be canceled. Herein, the second offset may be an offset associated with the B-gamma amplification stage.

In operation S110, the internal connection of the gamma amplifier may be controlled so that the B-gamma amplification stage operates in the low power mode during the sample period and the A-gamma amplification stage operates in the normal mode during the hold period. For example, during the sample period, the B-gamma amplification stage may be connected to a stage or node that consumes low power to sample a second offset of the gamma amplifier. The A-gamma amplification stage may be connected to a stage that outputs the voltage amplified in the A-gamma amplification stage externally and the first offset of the gamma amplifier may be canceled.

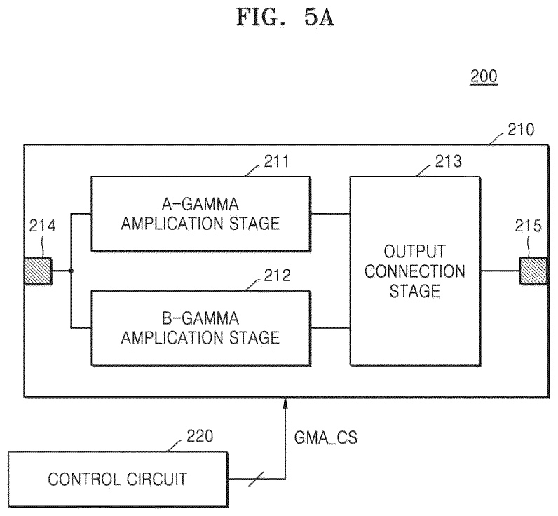

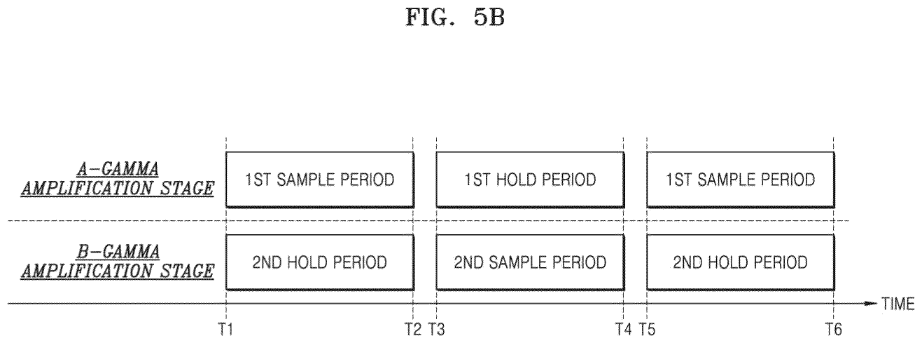

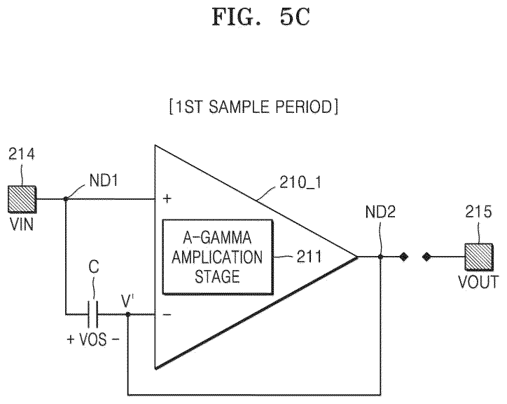

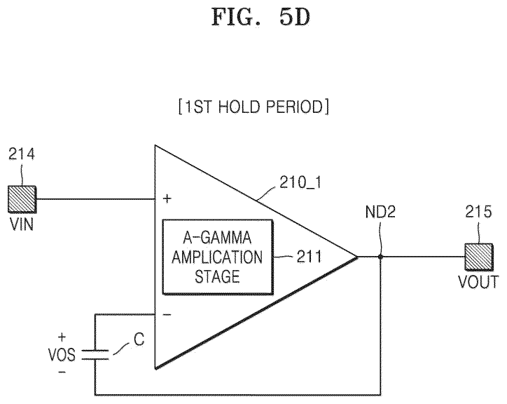

FIG. 5A is a block diagram schematically illustrating a gamma voltage generator 200 according to an embodiment, FIG. 5B is a diagram illustrating operations of an A-gamma amplification stage 211 and a B-gamma amplification stage 212 of FIG. 5A, according to an embodiment, FIG. 5C is a circuit diagram of a first amplification circuit 210_1 including the A-gamma amplification stage 211 of FIG. 5A in the first sample period, according to an embodiment, and FIG. 5D is a circuit diagram of the first amplification circuit 210_1 including the A-gamma amplification stage 211 of FIG. 5A in the first hold period, according to an embodiment.

Referring to FIG. 5A, the gamma voltage generator 200 may include a gamma amplifier 210 and a control circuit 220. The gamma amplifier 210 may include the A-gamma amplification stage 211, the B-gamma amplification stage 212, an output connection stage 213, an input terminal 214, and an output terminal 215.

As an embodiment, the A-gamma amplification stage 211 and the B-gamma amplification stage 212 may be connected to the input terminal 214 and may receive a voltage from the input terminal 214.

In an embodiment, the output connection stage 213 may control the internal connection of the gamma amplifier 210 so that the A-gamma amplification stage 211 and the B-gamma amplification stage 212 perform mutual ping-pong-based operations. For example, in some embodiments, the output connection stage 213 may include one or more switches to control the internal connection. However, embodiments are not limited thereto.

To help understanding, referring further to FIG. 5B, from time T1 to time T2 the output connection stage 213 may control the connection of the A-gamma amplification stage 211 so that the A-gamma amplification stage 211 operates during the first sample period and may control the connection of the B-gamma amplification stage 212 so that the B-gamma amplification stage 212 operates during the second hold period. That is, from time T1 to time T2, the A-gamma amplification stage 211 may be controlled to sample the first offset of the gamma amplifier 210 and the B-gamma amplification stage 212 may be controlled to perform an amplification operation in which the second offset of the gamma amplifier 210 is canceled. From time T1 to time T2, the A-gamma amplification stage 211 may be disconnected from the output terminal 215 and the B-gamma amplification stage 212 may be connected to the output terminal 215.

From time T3 to time T4, the output connection stage 213 may control the connection of the A-gamma amplification stage 211 so that the A-gamma amplification stage 211 operates during the first hold period and may control the connection of the B-gamma amplification stage 212 so that the B-gamma amplification stage 212 operates during the second sample period. That is, from time T3 to time T4, the A-gamma amplification stage 211 may be controlled to perform an amplification operation in which the first offset of the gamma amplifier 210 is canceled and the B-gamma amplification stage 212 may be controlled to sample the second offset of the gamma amplifier 210. From time T3 to time T4, the A-gamma amplification stage 211 may be connected to the output terminal 215 and the B-gamma amplification stage 212 may be disconnected from the output terminal 215.

From time T5 to time T6, the output connection stage 213 may control the connection of the A-gamma amplification stage 211 so that the A-gamma amplification stage 211 operates again during the first sample period and may control the connection of the B-gamma amplification stage 212 so that the B-gamma amplification stage 212 operates again during the second hold period. That is, from time T5 to time T6, the A-gamma amplification stage 211 may be controlled to re-sample the first offset of the gamma amplifier 210 and the B-gamma amplification stage 212 may be controlled to re-perform the amplification operation in which the second offset of the gamma amplifier 210 is canceled. From time T5 to time T6, the A-gamma amplification stage 211 may be disconnected from the output terminal 215 and the B-gamma amplification stage 212 may be connected to the output terminal 215. The first sample period and the first hold period may be repeated alternately in this manner, and the second sample period and the second hold period may also be repeated alternately in this manner.

In the manner described above, the output connection stage 213 may control the connection so that the A-gamma amplification stage 211 and the B-gamma amplification stage 212 perform mutual ping-pong-based operations. When the A-gamma amplification stage 211 operates in the first sample mode, the B-gamma amplification stage 212 may operate in the second hold mode, and when the A-gamma amplification stage 211 operates in the first hold mode, the B-gamma amplification stage 212 may operate in the second sample mode.

Referring further to FIG. 5C, the components included in the first amplification circuit 210_1 may vary depending on the first sample period and the first hold period. For example, in the first sample period, the first amplification circuit 210_1 may include the A-gamma amplification stage 211 and a stage that consumes low power (e.g., the sample driving stage). As another example, in the first sample period, the first amplification circuit 210_1 may include the A-gamma amplification stage 211, and the stage that consumes low power may be omitted.

During the first sample period, a positive input terminal of the first amplification circuit 210_1 may be connected to the input terminal 214 through a first node ND1 so that a first voltage VIN may be input, and a negative input terminal of the first amplification circuit 210_1 may be connected to a second node ND2, which is an output node of the first amplification circuit 210_1, and the second node ND2 may be disconnected from the output terminal 215. The positive input terminal of the first amplification circuit 210_1 may correspond to a positive input terminal of the A-gamma amplification stage 211, and the negative input terminal of the first amplification circuit 210_1 may correspond to a negative input terminal of the A-gamma amplification stage 211. During the first sample period, a capacitor C included in the gamma amplifier 210 may be connected between the first node ND1 and the second node ND2 and may be charged with a first offset VOS, which is a voltage difference between the first voltage VIN, which is a voltage of the first node ND1, and a voltage V′ of the second node ND2. That is, during the first sample mode, the first offset VOS of the first amplification circuit 210_1 may be sampled using the capacitor C. In some embodiments, the capacitor C may be referred to as a sampling capacitor. Because a target connected during the first sample period and a target connected during the first hold period are different in the A-gamma amplification stage 211, there may be a difference between the first offset VOS sampled during the first sample period and the actual first offset that has to be canceled during the first hold period. As an example to minimize the difference, the A-gamma amplification stage 211 may be connected such that the correlation with the first offset VOS is higher than a first threshold. That is, during the first sample period and the first hold period, the A-gamma amplification stage 211 may be connected such that most of the first offset VOS is determined by the A-gamma amplification stage 211 commonly included in the first amplification circuit 210_1. The stage connected to the A-gamma amplification stage 211 during the first sample period may be connected such that the correlation with the first offset VOS is lower than a second threshold.

Referring further to FIG. 5D, in the first hold period, the first amplification circuit 210_1 may include the A-gamma amplification stage 211 and a stage (e.g., a hold driving stage) that additionally amplifies the voltage amplified from the A-gamma amplification stage 211 and output the same through an output terminal 215.

In the first hold period, the first voltage VIN may be input to the positive input terminal of the first amplification circuit 210_1 through the input terminal 214 and the capacitor C charged with the first offset VOS may be connected between the negative input terminal of the first amplification circuit 210_1 and the output node of the first amplification circuit 210_1, so that the first offset VOS may be canceled from an output voltage VOUT of the output node ND2 of the first amplification circuit 210_1. As described above with reference to FIG. 5C, the A-gamma amplification stage 211 may be designed so that a difference between the actual first offset of the first amplification circuit 210_1 in the first hold period and the first offset VOS sampled in the first sample period is reduced. The stage connected to the A-gamma amplification stage 211 in the first hold period may be designed so that the correlation with the actual first offset of the first amplification circuit 210_1 in the first hold period is lower than the second threshold. The output node ND2 of the first amplification circuit 210_1 may be connected to the output terminal 215 and a voltage VOUT amplified by the first amplification circuit 210_1 may be output externally through the output terminal 215.

Referring back to FIG. 5A, the B-gamma amplification stage 212 may be included in the second amplification circuit based on the manner described above with reference to FIGS. 5C and 5D and may operate in the second sample period and the second hold period.

The control circuit 220 may generate a gamma amplifier control signal GMA_CS and provide the same to the gamma amplifier 210, and the output connection stage 213 may control the connection to the A-gamma amplification stage 211 and the B-gamma amplification stage 212 in the sample period or the hold period based on the gamma amplifier control signal GMA_CS.

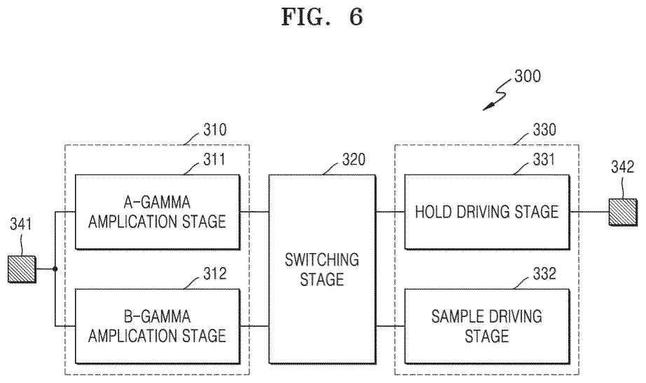

FIG. 6 is a block diagram illustrating a gamma amplifier 300 according to an embodiment.

Referring to FIG. 6, the gamma amplifier 300 may include a gamma amplification stage 310, a switching stage 320, a driving stage 330, an input terminal 341, and an output terminal 342. The gamma amplification stage 310 may include an A-gamma amplification stage 311 and a B-gamma amplification stage 312 that perform mutual ping-pong-based operations. The driving stage 330 may include a hold driving stage 331 and a sample driving stage 332. In some embodiments, the switching stage 320 and the driving stage 330 may be included in the output connection stage 213 of FIG. 5A. In some embodiments, the A-gamma amplification stage 311 and the B-gamma amplification stage 312 may be connected to the input terminal 341, and the hold driving stage 331 may be connected to the output terminal 342.

In an embodiment, the switching stage 320 may be connected to either the hold driving stage 331 or the sample driving stage 332 based on the operating period of the A-gamma amplification stage 311. In an embodiment, the switching stage 320 may be connected to one of the hold driving stage 331 or the sample driving stage 332 based on an operation period of the B-gamma amplification stage 312.

In an embodiment, the A-gamma amplification stage 311 and/or the B-gamma amplification stage 312 may perform a primary amplification operation on a voltage input from the input terminal 341, and the hold driving stage 331 and/or the sample driving stage 332 may perform a secondary amplification operation on a voltage amplified by one of the A-gamma amplification stage 311 or the B-gamma amplification stage 312. For example, the primary amplification operation may have a larger amplification gain than the secondary amplification operation.

In an embodiment, the sample driving stage 332 may consume less power than the hold driving stage 331. For example, the amount of current flowing in the sample driving stage 332 may be less than the amount of current flowing in the hold driving stage 331. As an example, the width of a first transistor included in the sample driving stage 332 may be narrower than the width of a second transistor included in the hold driving stage 331, and the amount of current flowing by the first transistor may be less than the amount of current flowing by the second transistor. As an example, a gate voltage applied to the first transistor included in the sample driving stage 332 may be different from a gate voltage applied to the second transistor so that the amount of current flowing by the first transistor is less than the amount of current flowing by the second transistor included in the hold driving stage 331.

In an embodiment, the gamma amplifier 300 may be configured such that most of the first offset is determined by the A-gamma amplification stage 311. For example, transistors included in the A-gamma amplification stage 311 may have a correlation with the first offset that is higher than the first threshold, and transistors included in the hold driving stage 331 and transistors included in the sample driving stage 332 may have a correlation with the first offset that is lower than the second threshold.

In an embodiment, the gamma amplifier 300 may be configured such that most of the second offset is determined by the B-gamma amplification stage 312. For example, the correlation between the transistors included in the B-gamma amplification stage 312 and the second offset may be higher than the first threshold, and the correlation between the transistors included in the hold driving stage 331 and the transistors included in the sample driving stage 332 and the second offset may be lower than the second threshold.

The first threshold and the second threshold may be values determined through a plurality of tests during a design stage or production stage for the gamma amplifier 300.

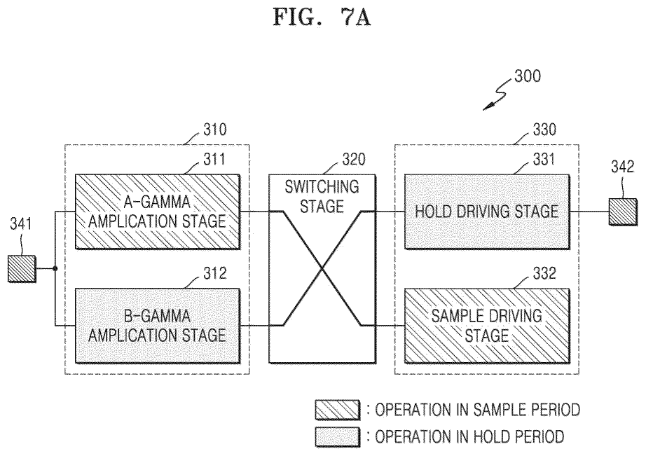

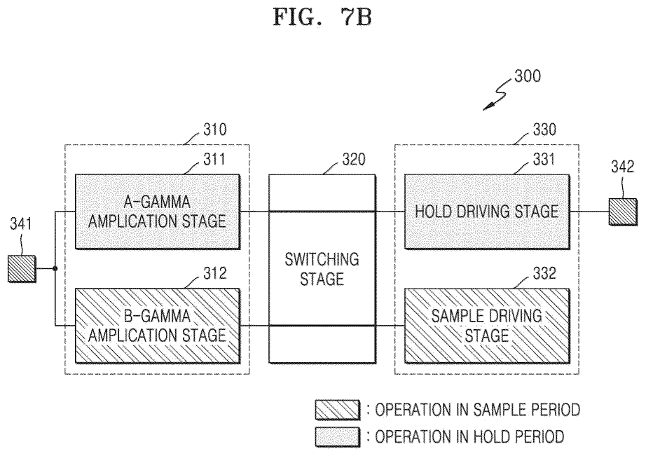

FIGS. 7A and 7B are diagrams illustrating the operation of the gamma amplifier 300 of FIG. 6, according to an embodiment. In FIG. 7A, the A-gamma amplification stage 311 operating during the first sample period and the B-gamma amplification stage 312 operating during a second hold period are described.

Referring to FIG. 7A, the switching stage 320 may connect the A-gamma amplification stage 311 to the sample driving stage 332 and the B-gamma amplification stage 312 to the hold driving stage 331. A voltage amplified by an amplification operation in which a first offset of a first amplification circuit including the A-gamma amplification stage 311 and the sample driving stage 332 is sampled and a second offset of a second amplification circuit including the B-gamma amplification stage 312 and the hold driving stage 331 is canceled may be output through an output terminal 342.

In an embodiment, the A-gamma amplification stage 311 may primarily amplify a first voltage input through the input terminal 341 and output the same to the sample driving stage 332. The sample driving stage 332 may secondarily amplify a second voltage output from the A-gamma amplification stage 311 and feed back the amplified second voltage to the A-gamma amplification stage 311. A first offset may be sampled based on a difference between the first voltage and the amplified second voltage.

In an embodiment, the B-gamma amplification stage 312 may primarily amplify a third voltage input through the input terminal 341 and output the same to the hold driving stage 331. The hold driving stage 331 may secondarily amplify the third voltage output from the B-gamma amplification stage 312 and output the amplified third voltage through the output terminal 342. The second offset may be canceled in the amplification operation of the B-gamma amplification stage 312 and the hold driving stage 331.

Referring to FIG. 7B, the A-gamma amplification stage 311 operating during the first hold period and the B-gamma amplification stage 312 operating during the second sample period are described.

Referring further to FIG. 7B, the switching stage 320 may connect the A-gamma amplification stage 311 to the hold driving stage 331 and the B-gamma amplification stage 312 to the sample driving stage 332. A voltage amplified by an amplification operation in which the first offset of the first amplification circuit including the A-gamma amplification stage 311 and the hold driving stage 331 is canceled may be output through the output terminal 342. The second offset of the second amplification circuit including the B-gamma amplification stage 312 and the sample driving stage 332 may be sampled.

In an embodiment, the A-gamma amplification stage 311 may primarily amplify the first voltage input through the input terminal 341 and output the same to the hold driving stage 331. The hold driving stage 331 may secondarily amplify the second voltage output from the A-gamma amplification stage 311 and output the amplified second voltage through the output terminal 342. The first offset may be canceled in the amplification operation of the A-gamma amplification stage 311 and the hold driving stage 331.

In an embodiment, the B-gamma amplification stage 312 may primarily amplify a third voltage input through the input terminal 341 and output the same to the sample driving stage 332. The sample driving stage 332 may secondarily amplify a fourth voltage output from the B-gamma amplification stage 312 and feed back the amplified fourth voltage to the B-gamma amplification stage 312. The second offset may be sampled based on a difference between the third voltage and the amplified fourth voltage.

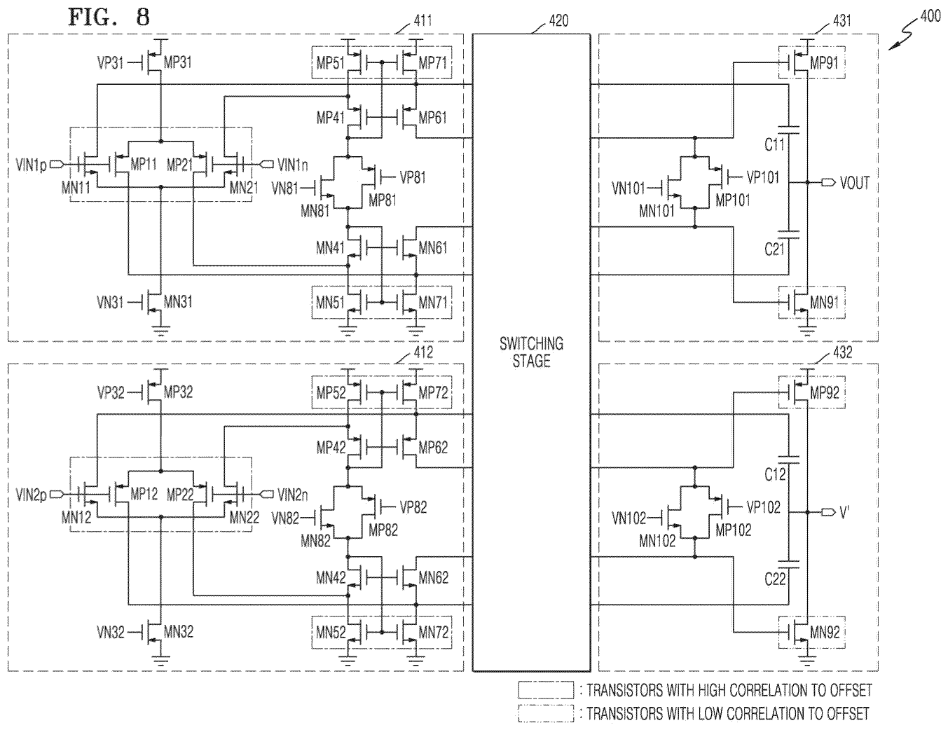

FIG. 8 is a circuit diagram illustrating a gamma amplifier 400 according to an embodiment.

Referring to FIG. 8, the gamma amplifier 400 may include an A-gamma amplification stage 411, a B-gamma amplification stage 412, a switching stage 420, a hold driving stage 431, and a sample driving stage 432.

In an embodiment, the A-gamma amplification stage 411 may include a plurality of first transistors MN11 to MN31 and MP11 to MP31 and a plurality of second transistors MN41 to MN81 and MP41 to MP81. Herein, the first transistors MN11 to MN31 and MP11 to MP31 may form a first sub-amplification stage having a first amplification gain, and the second transistors MN41 to MN81 and MP41 to MP81 may form a second sub-amplification stage having a second amplification gain. Accordingly, the A-gamma amplification stage 411 may have an amplification gain determined by the product of the first amplification gain and the second amplification gain.

In an embodiment, a gate terminal of the transistor MN11 and a gate terminal of the transistor MP11 may be positive input terminals of the A-gamma amplification stage 411, to which a positive voltage VIN1p received from the input terminal of the gamma amplifier 400 may be input. A gate terminal of the transistor MP21 and a gate terminal of the transistor MN21 may be negative input terminals of the A-gamma amplification stage 411, into which a negative voltage VIN1n may be input. In the transistor MP31, a power supply voltage may be applied to a source terminal, a voltage VP31 may be applied to a gate terminal, and a drain terminal may be connected to source terminals of the transistors MP11 and MP21. In the transistor MN31, a source terminal may be grounded, a voltage VN31 may be applied to a gate terminal, and a drain terminal may be connected to source terminals of the transistors MN11 and MN21.

In an embodiment, in the transistor MP51, a power supply voltage may be applied to a source terminal, a gate terminal may be connected to a gate terminal of the transistor MP71, and a drain terminal of the transistor MP41, and a drain terminal may be connected to a source terminal of the transistor MP41 and a drain terminal of the transistor MN21. In the transistor MP71, a power supply voltage may be applied to a source terminal, a gate terminal may be connected to a gate terminal of the transistor MP51 and the drain terminal of the transistor MP41, and a drain terminal may be connected to a source terminal of the transistor MP61, of which the connection may be controlled by the switching stage 420. In the transistor MP41, a source terminal may be connected to a drain terminal of the transistor MP51 and the drain terminal of the transistor MN21, a gate terminal may be connected to a gate terminal of the transistor MP61, and a drain terminal may be connected to a source terminal of the transistor MP81 and a drain terminal of the transistor MN81. In the transistor MP61, a source terminal may be connected to the drain terminal of the transistor MP71 and a drain terminal of the transistor MN11, a gate terminal may be connected to the gate terminal of the transistor MP41, and a connection of a drain terminal may be controlled by the switching stage 420. In the transistor MP81, a source terminal may be connected to the drain terminal of the transistor MP41, the gate terminal of the transistor MP51, and the drain terminal of the transistor MN81, and a voltage VP81 may be applied to a gate terminal, and a drain terminal may be connected to the drain terminal of the transistor MN41, the gate terminal of the transistor MN51, and the source terminal of the transistor MN81. In the transistor MN81, the drain terminal may be connected to the drain terminal of the transistor MP41, the gate terminal of the transistor MP51, and the source terminal of the transistor MP81, and a voltage VN81 may be applied to a gate terminal, and a source terminal may be connected to the drain terminal of the transistor MN41, the gate terminal of the transistor MN51, and the drain terminal of the transistor MP81. In the transistor MN41, a drain terminal may be connected to the drain terminal of the transistor MP81, the source terminal of the transistor MN81, and the gate terminal of the transistor MN51, a gate terminal may be connected to the gate terminal of the transistor MN61, and a source terminal may be connected to the drain terminal of the transistor MN51 and the drain terminal of the transistor MP21. In the transistor MN61, a connection of a drain terminal may be controlled by the switching stage 420, a gate terminal may be connected to the gate terminal of the transistor MN41, and a source terminal may be connected to the drain terminal of the transistor MN71 and the drain terminal of the transistor MP11, of which the connection may be controlled by the switching stage 420. In the transistor MN51, a drain may be is connected to the source terminal of the transistor MN41 and the drain terminal of the transistor MP21, a gate terminal may be connected to the gate terminal of the transistor MN71 and the drain terminal of the transistor MN41, and a source terminal may be grounded. In the transistor MN71, a drain terminal may be connected to the source terminal of the transistor MN61, a gate terminal may be connected to the gate terminal of the transistor MN51 and the drain terminal of the transistor MN41, and a source terminal may be grounded.

In an embodiment, the B-gamma amplification stage 412 may include a plurality of third transistors MN12 to MN32 and MP12 to MP32 and a plurality of fourth transistors MN42 to MN82 and MP42 to MP82. Herein, the third transistors MN12 to MN32 and MP12 to MP32 may form a third sub-amplification stage having a first amplification gain, and the fourth transistors MN42 to MN82 and MP42 to MP82 may form a fourth sub-amplification stage having a second amplification gain. Accordingly, the B-gamma amplification stage 412 may have an amplification gain determined by the product of the first amplification gain and the second amplification gain. The B-gamma amplification stage 412 may be implemented in the same manner as the A-gamma amplification stage 411, and thus, details thereof are omitted for convenience of description and for conciseness.

In an embodiment, the hold driving stage 431 may include a plurality of fifth transistors MN91, MN101, MP91, and MP101 and first capacitors C11 and C21. For example, an amplification gain of the hold driving stage 431 may be lower than amplification gains of the A-gamma amplification stage 411 and the B-gamma amplification stage 412.

In an embodiment, in the transistor MP91, a power supply voltage may be applied to a source terminal, a gate terminal may be connected to a source terminal of the transistor MP101 and a drain terminal of the transistor MN101, of which the connection may be controlled by the switching stage 420, and a drain terminal may be connected to an output terminal from which the amplified voltage VOUT is output and a node shared by the first capacitors C11 and C21. In the transistor MN91, the drain terminal may be connected to the drain terminal of the transistor MP91, a gate terminal may be connected to the drain terminal of the transistor MP101 and the source terminal of the transistor MN101, of which the connection may be controlled by the switching stage 420, and a source terminal may be grounded. In the transistor MP101, a source terminal may be connected to the gate terminal of the transistor MP91 and the drain terminal of the transistor MN101, a gate terminal may be applied with a voltage VP101, and a drain terminal may be connected to the gate terminal of the transistor MP91 and a source terminal of the transistor MN101. In the transistor MN101, a drain terminal may be connected to the gate terminal of the transistor MP91 and the source terminal of the transistor MP101, a gate terminal is applied with a voltage VN101, and a source terminal may be connected to the gate terminal of the transistor MN91 and the drain terminal of the transistor MP101. In the capacitor C11, one end may be controlled by the switching stage 420, and the other end may be connected to the other end of the capacitor C21. In the capacitor C21, one end may be controlled by the switching stage 420, and the other end may be connected to the other end of the capacitor C11.

In an embodiment, the sample driving stage 432 may include a plurality of sixth transistors MN92, MN102, MP92, and MP102 and the second capacitors C12 and C22. For example, the amplification gain of the sample driving stage 432 may be lower than the amplification gains of the A-gamma amplification stage 411 and the B-gamma amplification stage 412. For example, the amplification gain of the sample driving stage 432 may be equal to or similar to the amplification gain of the hold driving stage 431. The sample driving stage 432 may be implemented to have the same connection structure as the hold driving stage 431, so details thereof are omitted for convenience of description and for conciseness. However, the output node of the sample driving stage 432 is disconnected from the output terminal of the gamma amplifier 400, and the voltage V′ of the output node may be provided to the A-gamma amplification stage 411 or the B-gamma amplification stage 412.

In an embodiment, the widths of the transistor MP92 and the transistor MN92 of the sample driving stage 432 may be narrower than the widths of the transistor MP91 and the transistor MN91 of the hold driving stage 431. In an embodiment, the voltage VP102 of the sample driving stage 432 may be higher in level than the voltage VP101 of the hold driving stage 431, and the voltage VN102 of the sample driving stage 432 may be lower in level than the voltage VN101 of the hold driving stage 431. Through the embodiments, power consumed in the sample driving stage 432 may be less than power consumed in the hold driving stage 431.

In an embodiment, the transistors MN11, MN21, MN51, MN71, MP11, MP21, MP51, and MP71 indicated by the dashed lines in the A-gamma amplification stage 411 may have a high correlation with the first offset, and the transistors MP91, MN91, MP92, and MN92 indicated by the dashed lines in the hold driving stage 431 and the sample driving stage 432 may have a low correlation with the first offset. Accordingly, the first offset of the first amplification circuit including the A-gamma amplification stage 411 may be largely determined by the transistors MN11, MN21, MN51, MN71, MP11, MP21, MP51, and MP71.

In an embodiment, the transistors MN12, MN22, MN52, MN72, MP12, MP22, MP52, and MP72 indicated by the dashed lines in the B-gamma amplification stage 412 may have a high correlation with the second offset, and the transistors MP91, MN91, MP92, and MN92 indicated by the dashed lines in the hold driving stage 431 and the sample driving stage 432 may have a low correlation with the second offset. Accordingly, the second offset of the second amplification circuit including the B-gamma amplification stage 412 may be largely determined by the transistors MN12, MN22, MN52, MN72, MP12, MP22, MP52, and MP72.

However, the structure of the gamma amplifier 400 illustrated in FIG. 8 is merely an embodiment and is not limited thereto, and the structure of the gamma amplifier 400 may be implemented variously.

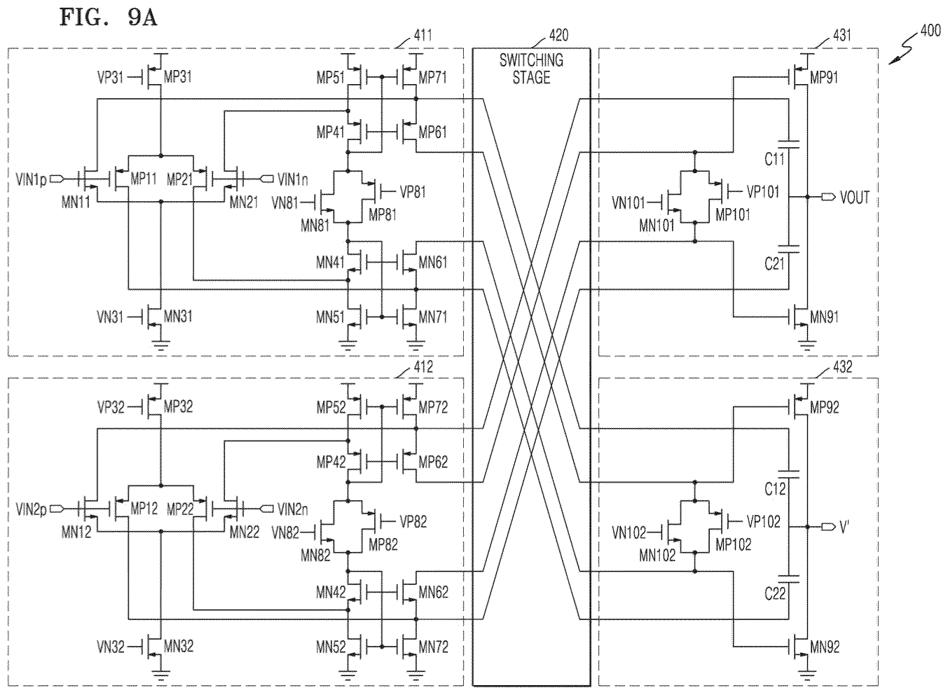

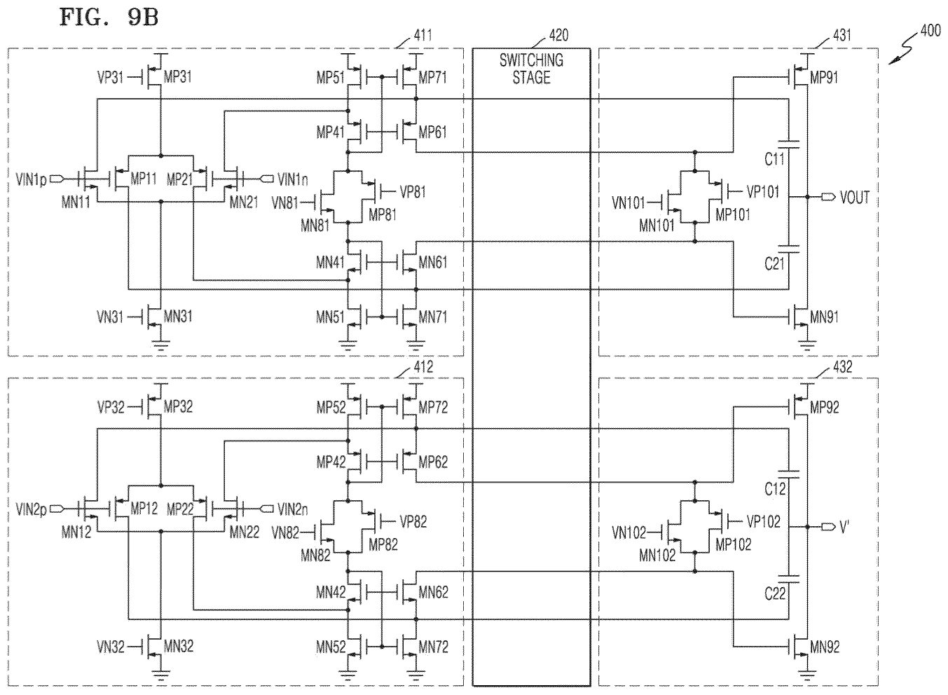

FIGS. 9A and 9B are diagrams illustrating the operation of the gamma amplifier 400 of FIG. 8, according to an embodiment. In FIGS. 9A and 9B, the structure and function of the components in FIGS. 9A and 9B are similar to the structure and function of like components in FIG. 8 and thus the same description as that given above with reference to FIG. 8 is omitted for conciseness. Referring to FIG. 9, the A-gamma amplification stage 411 operating in the first sample period and the B-gamma amplification stage 412 operating in the second hold period are described.

Referring to FIG. 9A, the switching stage 420 may connect the A-gamma amplification stage 411 to the sample driving stage 432 and the B-gamma amplification stage 412 to the hold driving stage 431. The A-gamma amplification stage 411 and the sample driving stage 432 may be interconnected to form a first amplification circuit, and the B-gamma amplification stage 412 and the hold driving stage 431 may be interconnected to form a second amplification circuit. An amplification gain of the first amplification circuit or the second amplification circuit may be expressed by Mathematical Formula 1.

$${G}_{T} = ( - {g}_{m 1} {r}_{o 1} ) \times ( - {g}_{m 2} {r}_{o 2} ) \qquad [ Mathematical Formula 1 ]$$

In the Mathematical Formula 1, GT, as a positive amplification gain, may be the amplification gain of the first amplification circuit or the second amplification circuit, −gₘ₁rₒ₁ as a negative amplification gain, may be the amplification gain of the A-gamma amplification stage 411 or the B-gamma amplification stage 412, and −gₘ₂rₒ₂, as a negative amplification gain, may be the amplification gain of the hold driving stage 431 or the sample driving stage 432. The value gₘ₁ may be an amplification gain by the first sub-amplification stage of the A-gamma amplification stage 411 or the third sub-amplification stage of the B-gamma amplification stage 412, and rₒ₁ may be an amplification gain by the second sub-amplification stage of the A-gamma amplification stage 411 or the fourth sub-amplification stage of the B-gamma amplification stage 412.

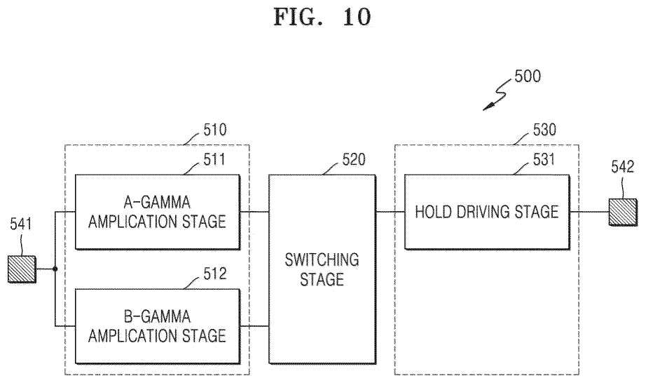

In an embodiment in which the sample driving stage 432 is omitted among the embodiments to be described below, the positive input terminal and the negative input terminal of the A-gamma amplification stage 411 or the B-gamma amplification stage 412 may be mutually switched so that the first amplification circuit or the second amplification circuit in the sample period has a positive amplification gain. In the hold period, the positive and negative input terminals that were switched mutually in the sample period may be restored. Details thereof are described with reference to FIG. 10 below, etc.

Referring back to FIG. 9A again, as an example, the switching stage 420 may connect the drain terminal of the transistor MP71 of the A-gamma amplification stage 411 to one end of the capacitor C12 of the sample driving stage 432, the drain terminal of the transistor MP61 of the A-gamma amplification stage 411 to the source terminal of the transistor MP102 of the sample driving stage 432, the drain terminal of the transistor MN61 of the A-gamma amplification stage 411 to the drain terminal of the transistor MP102 of the sample driving stage 432, and the drain terminal of the transistor MN71 of the A-gamma amplification stage 411 to one end of the capacitor C22 of the sample driving stage 432. The voltage V′ of the output node of the sample driving stage 432 may be provided as the negative voltage VIN1n of the A-gamma amplification stage 411.

The switching stage 420 may connect the drain terminal of the transistor MP72 of the B-gamma amplification stage 412 to one end of the capacitor C11 of the hold driving stage 431, the drain terminal of the transistor MP62 of the B-gamma amplification stage 412 to the source terminal of the transistor MP101 of the hold driving stage 431, the drain terminal of the transistor MN62 of the B-gamma amplification stage 412 to the drain terminal of the transistor MP101 of the hold driving stage 431, and the drain terminal of the transistor MN72 of the B-gamma amplification stage 412 to one end of the capacitor C21 of the hold driving stage 431.

Referring to FIG. 9B, the A-gamma amplification stage 411 operating in the first hold period and the B-gamma amplification stage 412 operating in the second sample period are described.

Referring further to FIG. 9B, the switching stage 420 may connect the A-gamma amplification stage 411 to the hold driving stage 431 and the B-gamma amplification stage 412 to the sample driving stage 432. As an example, the switching stage 420 may connect the drain terminal of the transistor MP71 of the A-gamma amplification stage 411 to one end of the capacitor C11 of the hold driving stage 431, the drain terminal of the transistor MP61 of the A-gamma amplification stage 411 to the source terminal of the transistor MP101 of the hold driving stage 431, the drain terminal of the transistor MN61 of the A-gamma amplification stage 411 to the drain terminal of the transistor MP101 of the hold driving stage 431, and the drain terminal of the transistor MN71 of the A-gamma amplification stage 411 to one end of the capacitor C21 of the hold driving stage 431. The switching stage 420 may connect the drain terminal of the transistor MP72 of the B-gamma amplification stage 412 to one terminal of the capacitor C12 of the sample driving stage 432, the drain terminal of the transistor MP62 of the B-gamma amplification stage 412 to the source terminal of the transistor MP102 of the sample driving stage 432, the drain terminal of the transistor MN62 of the B-gamma amplification stage 412 to the drain terminal of the transistor MP102 of the sample driving stage 432, and the drain terminal of the transistor MN72 of the B-gamma amplification stage 412 to one end of the capacitor C22 of the sample driving stage 432.

FIG. 10 is a block diagram illustrating a gamma amplifier 500 according to an embodiment. Referring to FIG. 10, the structure and function of the components in FIG. 10 are similar to the structure and function of like components in FIG. 6 and thus the same description as that of the gamma amplifier 300 of FIG. 6 is omitted for conciseness.

Referring to FIG. 10, the gamma amplifier 500 may include a gamma amplification stage 510, a switching stage 520, a driving stage 530, an input terminal 541, and an output terminal 542. The gamma amplification stage 510 may include an A-gamma amplification stage 511 and a B-gamma amplification stage 512 that perform mutual ping-pong-based operations. The driving stage 530 may include a hold driving stage 531. That is, compared to the driving stage 330 of FIG. 6, the sample driving stage may be omitted in the driving stage 530. Through this omission, more power may be saved in the amplification operation in the sample period than in FIG. 6. The switching stage 520 and the driving stage 530 may be included in the output connection stage 213 of FIG. 5A. The A-gamma amplification stage 511 and the B-gamma amplification stage 512 may be connected to the input terminal 541, and the hold driving stage 531 may be connected to the output terminal 542.

In an embodiment, the switching stage 520 may be connected to one of the hold driving stage 531 or the sampling node based on the operating period of the A-gamma amplification stage 511. The switching stage 520 may be connected to one of the hold driving stage 531 or the sampling node based on the operation period of the B-gamma amplification stage 512. Herein, a voltage of the sampling node may correspond to a voltage used to sample an offset.

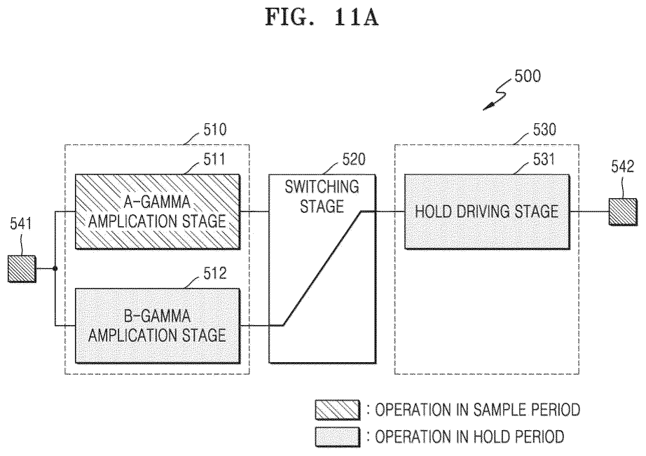

FIGS. 11A and 11B are diagrams illustrating the operation of the gamma amplifier 500 of FIG. 10, according to an embodiment. Referring to FIG. 11A, the A-gamma amplification stage 511 operating during the first sample period and the B-gamma amplification stage 512 operating during the second hold period are described. In FIGS. 11A and 11B, the structure and function of the components in FIGS. 11A and 11B are similar to the structure and function of like components in FIGS. 7A and 7B and thus the same descriptions as those given above with reference to FIGS. 7A and 7B are omitted for conciseness.

Referring to FIG. 11A, the switching stage 520 may connect the A-gamma amplification stage 511 to the first sampling node and the B-gamma amplification stage 512 to the hold driving stage 531. A voltage amplified by an amplification operation in which a first offset of a first amplification circuit including the A-gamma amplification stage 511 and a first sampling node is sampled and a second offset of a second amplification circuit including the B-gamma amplification stage 512 and the hold driving stage 531 is canceled may be output through the output terminal 542.

In an embodiment, in the A-gamma amplification stage 511, positive and negative input terminals may be switched mutually as the first hold period is switched to the first sample period. In the A-gamma amplification stage 511, the switched input terminals may be restored as the first sample period is switched to the first hold period. As an example, the positive input terminal in the first hold period may receive an input as the negative input terminal in the first sample period, and the negative input terminal in the first hold period may receive an input as the positive input terminal in the first sample period. This configuration and operation may be to convert a negative amplification gain of the A-gamma amplification stage 511 into a positive amplification gain, because an amplification operation is performed by the A-gamma amplification stage 511 of the first amplification circuit in the first sample period. However, this is only an example and embodiments are not limited thereto, and various implementation examples other than switching the positive and negative input terminals may be applied.

In an embodiment, the A-gamma amplification stage 511 may amplify a first voltage input through the input terminal 541 and output the same to a first sampling node. A voltage of the first sampling node may be fed back to the A-gamma amplification stage 511, so that the first offset may be sampled based on a difference between the first voltage and the feedback voltage.

Referring to FIG. 11B, the A-gamma amplification stage 511 operating during the first hold period and the B-gamma amplification stage 512 operating during the second sample period are described.

Referring further to FIG. 11B, the switching stage 520 may connect the A-gamma amplification stage 511 to the hold driving stage 531 and the B-gamma amplification stage 512 to the second sampling node. In some embodiments, the first sampling node and the second sampling node may be different nodes or the same node. A voltage amplified by an amplification operation in which the first offset of the first amplification circuit including the A-gamma amplification stage 511 and the hold driving stage 531 is canceled may be output through the output terminal 542. A second offset of a second amplification circuit including the B-gamma amplification stage 512 and the second sampling node may be sampled.

In an embodiment, in the B-gamma amplification stage 512, the positive input terminal and the negative input terminal may be mutually switched as the second hold period is switched to the second sample period. The B-gamma amplification stage 512 may restore the switched input terminals as the second sample period is switched to the second hold period. As an example, the positive input terminal in the second hold period may receive input as the negative input terminal in the second sample period, and the negative input terminal in the second hold period may receive input as the positive input terminal in the second sample period.

In an embodiment, the B-gamma amplification stage 512 may amplify a third voltage input through the input terminal 541 and output the same to the second sampling node. A voltage of the second sampling node may be fed back to the B-gamma amplification stage 512, so that a second offset may be sampled based on a difference between the third voltage and the feedback voltage.

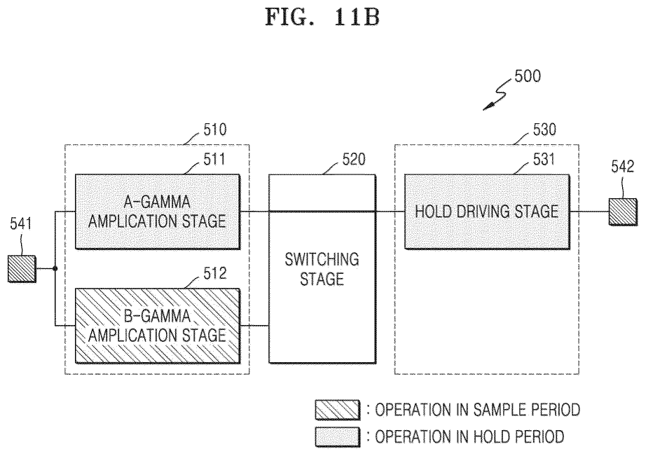

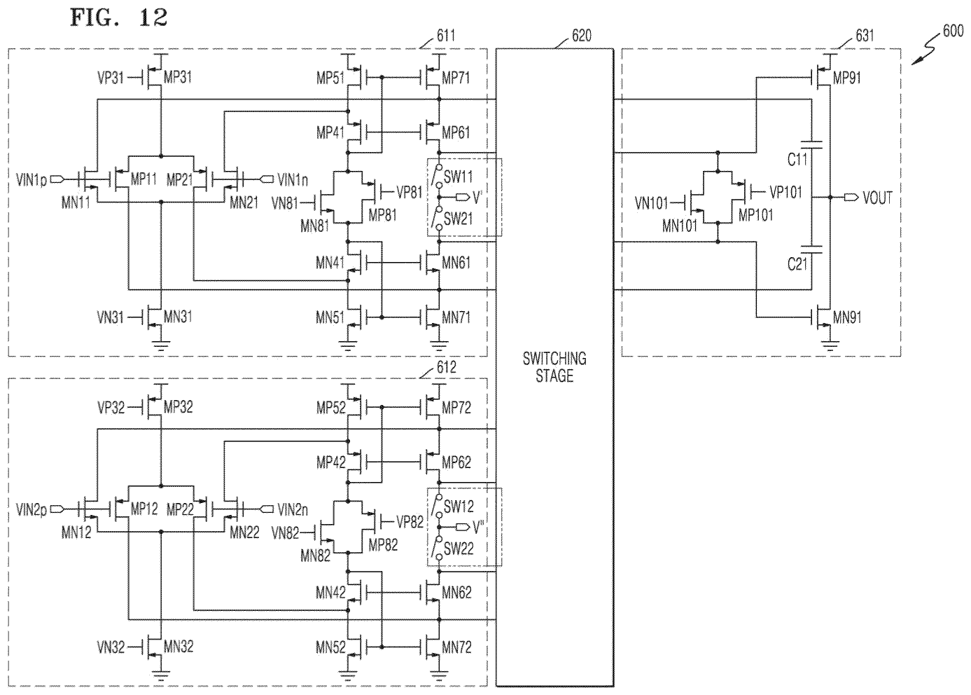

FIG. 12 is a circuit diagram illustrating a gamma amplifier 600 according to an embodiment. In FIG. 12, the structure and function of the components in FIG. 12 are similar to the structure and function of like components in FIG. 8. Hereinafter, a structural difference between the gamma amplifier 600 of FIG. 12 and the gamma amplifier 400 of FIG. 8 is described for conciseness.

Referring to FIG. 12, the gamma amplifier 600 may include an A-gamma amplification stage 611, a B-gamma amplification stage 612, a switching stage 620, and a hold driving stage 631.

In an embodiment, compared to the gamma amplifier 400 of FIG. 8, in the gamma amplifier 600, the sample driving stage 432 of FIG. 8 may be omitted, the A-gamma amplification stage 611 may further include first switching elements SW11 and SW21, and the B-gamma amplification stage 612 may further include second switching elements SW12 and SW22. In some embodiments, the first switching elements SW11 and SW21 and the second switching elements SW12 and SW22 may be included in the switching stage 620.

In an embodiment, in the switching element SW11 of the A-gamma amplification stage 611, one end may be connected to the drain terminal of the transistor MP61 and the other end may be connected to the other end of the switching element SW21 to share the first sampling node. In the first sample period, the voltage V′ of the first sampling node may be fed back to the A-gamma amplification stage 611 for sampling of the first offset. In the switching element SW21 of the A-gamma amplification stage 611, one end may be connected to the drain terminal of the transistor MN61.

In an embodiment, in the switching element SW12 of the B-gamma amplification stage 612, one end may be connected to the drain terminal of the transistor MP62 and the other end may be connected to the other end of the switching element SW22 to share the second sampling node. In the second sample period, a voltage V″ of the second sampling node may be fed back to the B-gamma amplification stage 612 for sampling of the second offset. In the switching element SW22 of the B-gamma amplification stage 612, one end may be connected to the drain terminal of the transistor MN62.

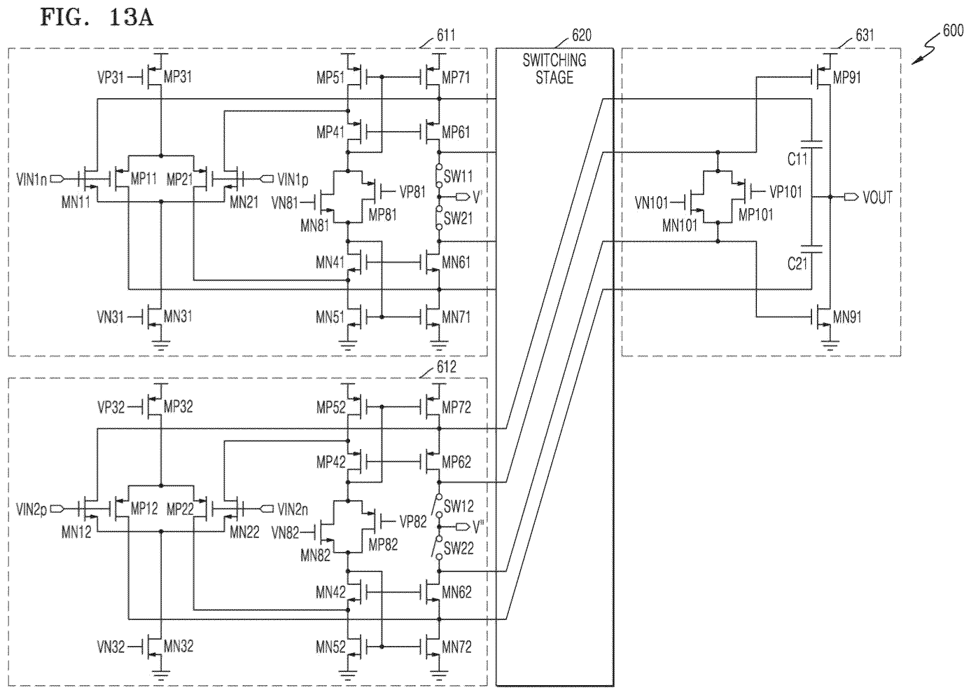

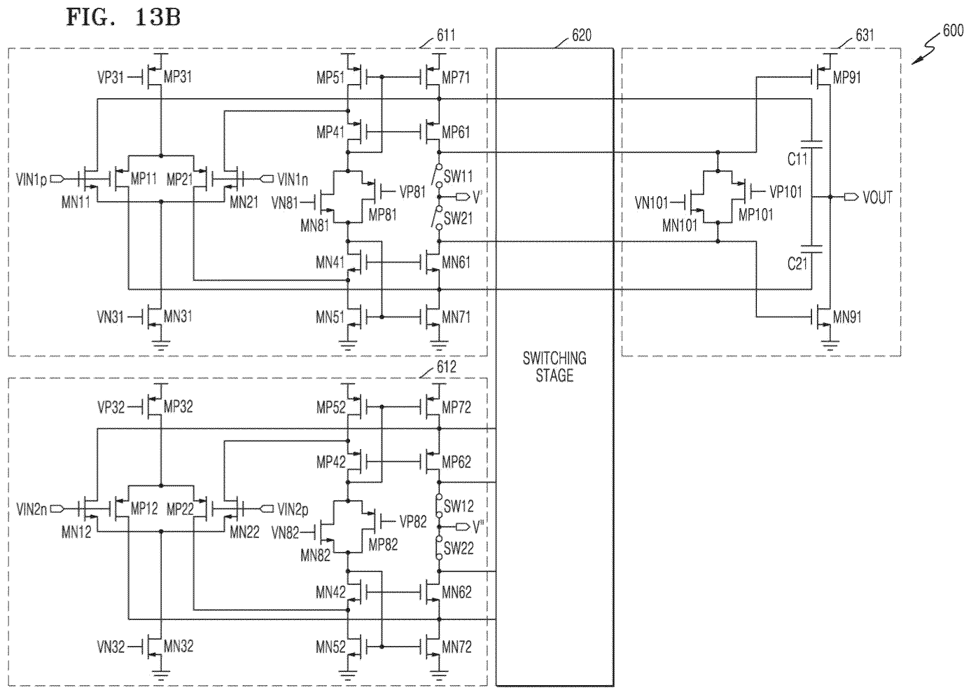

FIGS. 13A and 13B are diagrams illustrating the operation of the gamma amplifier 600 of FIG. 12. In FIGS. 13A and 13B, the structure and function of the components in FIGS. 13A and 13B are similar to the structure and function of like components in FIG. 12 and thus the same descriptions as those given above with reference to FIGS. 9A, 9B, and 12 are omitted for conciseness. Referring to FIG. 13A, an A-gamma amplification stage 611 operating during the first sample period and a B-gamma amplification stage 612 operating during the second hold period are described.

Referring to FIG. 13A, the switching stage 620 may connect the A-gamma amplification stage 611 to the first sampling node and the B-gamma amplification stage 612 to the hold driving stage 631. The A-gamma amplification stage 611 and the first sampling node may be interconnected to form a first amplification circuit, and the B-gamma amplification stage 612 and the hold driving stage 631 may be interconnected to form a second amplification circuit.

In an embodiment, the switching stage 620 may turn on the first switching elements SW11 and SW21 of the A-gamma amplification stage 611 and turn off the second switching elements SW12 and SW22 of the B-gamma amplification stage 612.

In an embodiment, the positive and negative input terminals of the A-gamma amplification stage 611 may be switched with each other so that the voltage V′ of the first sampling node may be provided as the positive voltage VIN1p of the A-gamma amplification stage 611. As an example, the positive voltage VIN1p may be input to the gate terminals of the transistor MP21 and the transistor MN21. The gate terminals of the transistor MP11 and the transistor MN11 may receive the negative voltage VIN1n.

In FIG. 13B, the A-gamma amplification stage 611 operating during the first hold period and the B-gamma amplification stage 612 operating during the second sample period are described.

Referring further to FIG. 13B, the switching stage 620 may connect the A-gamma amplification stage 611 to the hold driving stage 631 and the B-gamma amplification stage 612 to the second sampling node. The A-gamma amplification stage 611 and the hold driving stage 631 may be interconnected to form a first amplification circuit, and the B-gamma amplification stage 612 and the second sampling node may be interconnected to form a second amplification circuit.

In an embodiment, the switching stage 620 may turn off the first switching elements SW11 and SW21 of the A-gamma amplification stage 611 and turn on the second switching elements SW12 and SW22 of the B-gamma amplification stage 612.

In an embodiment, the switched positive and negative input terminals of the A-gamma amplification stage 611 may be restored. As an example, the negative voltage VIN1n may be input to the gate terminals of the transistor MP21 and the transistor MN21. The gate terminals of the transistor MP11 and the transistor MN11 may receive the positive voltage VIN1p.

In an embodiment, the positive and negative input terminals of the B-gamma amplification stage 612 may be switched so that the voltage V″ of the second sampling node may be provided as the positive voltage VIN2p of the B-gamma amplification stage 612. As an example, the positive voltage VIN2p may be input to the gate terminals of the transistor MP22 and the transistor MN22. The gate terminals of the transistor MP12 and the transistor MN12 may receive the negative voltage VIN2n.

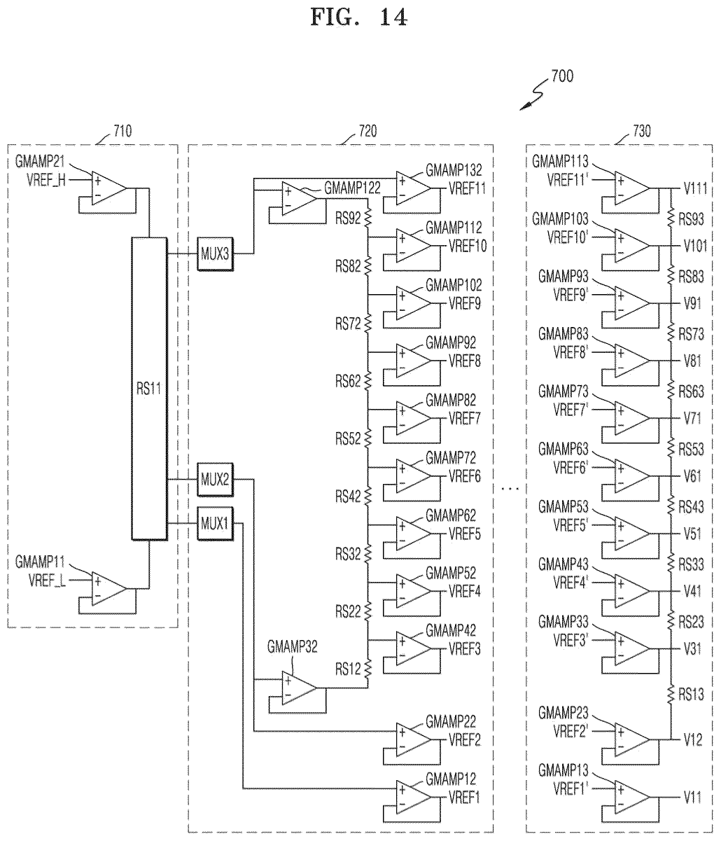

FIG. 14 is a block diagram illustrating a gamma voltage generator 700 according to an embodiment.

Referring to FIG. 14, the gamma voltage generator 700 may include a reference voltage generating circuit 710, a reference voltage selecting circuit 720, and a gamma voltage output circuit 730. For example, in the gamma voltage output circuit 730, the voltage buffer circuit 103 of FIG. 2 may be included in the gamma voltage output circuit 104.

In an embodiment, the reference voltage generating circuit 710 may include a plurality of first gamma amplifiers GMAMP11 and GMAMP21 and a first resistor string RS11. The gamma amplifier GMAMP11 may receive a low-level reference voltage VREF_L, amplify the received low-level reference voltage VREF_L, and output the same to the first resistor string RS11, and the gamma amplifier GMAMP21 may receive a high-level reference voltage VREF_H, amplify the received high-level reference voltage VREF_H, and output the same to the first resistor string RS11. The first resistor string RS11 may include resistors that are connected in series and share nodes and may output first reference voltages to the reference voltage selecting circuit 720 through the nodes.

In an embodiment, the reference voltage selecting circuit 720 may include a plurality of multiplexers MUX1 to MUX3, a plurality of second gamma amplifiers GMA MP12 to GMAMP132, and second resistor strings RS12 to RS92. The first multiplexer MUX1 may select one of the received reference voltages and output the selected reference voltage to the gamma amplifier GMAMP12. The second multiplexer MUX2 may select one of the received first reference voltages and output the selected first reference voltage to the gamma amplifier GMAMP22 and the gamma amplifier GMAMP32. The third multiplexer MUX3 may select one of the received first reference voltages and output the selected first reference voltage to the gamma amplifier GMAMP122 and the gamma amplifier GMAMP132. The second gamma amplifiers GMAMP12 to GMAMP132 may amplify the received first reference voltage or a reference voltage having a level adjusted by the second resistor strings RS12 to RS92 and output a plurality of second reference voltages VREF1 to VREF11.

In an embodiment, the gamma voltage output circuit 730 may include a plurality of third gamma amplifiers GMAMP13 to GMA MP113 and third resistor strings RS13 to RS93. The third gamma amplifiers GMAMP13 to GMAMP113 may each amplify one of received third reference voltages VREF1′ to VREF11′, and the levels of the amplified voltages are adjusted by the third resistor strings RS13 to RS93 so that a plurality of gamma voltages V11 to V111 may be output. For example, the third reference voltages VREF1′ to VREF11′ may be generated from the second reference voltages VREF1 to VREF11 or may be the same voltages.

In an embodiment, the implementation example of the gamma amplifier (hereinafter referred to as a first type gamma amplifier) described above with reference to FIG. 6 may be applied to the first to third gamma amplifiers GMAMP11, GMAMP21, GMAMP12 to GMAMP132, and GMAMP13 to GMAMP113.

In some embodiments, the implementation example of the gamma amplifier (hereinafter referred to as a second type gamma amplifier) described above with reference to FIG. 10 may be applied to the first to third gamma amplifiers GMAMP11, GMAMP21, GMAMP12 to GMAMP132, and GMAMP13 to GMAMP113.

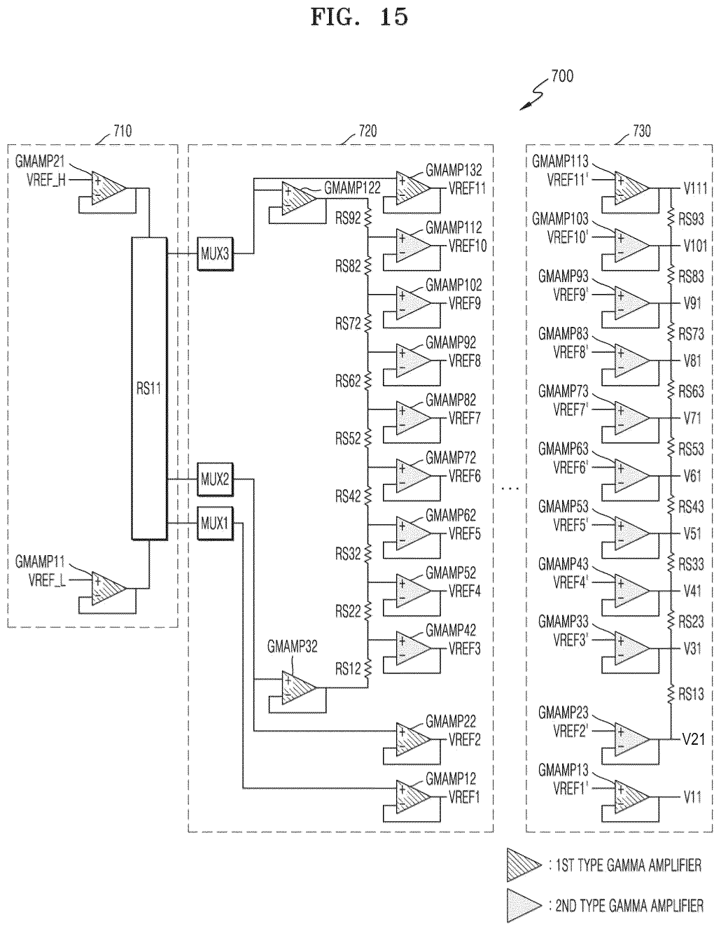

FIG. 15 is a diagram illustrating an implementation example of gamma amplifiers included in the gamma voltage generator 700 of FIG. 14, according to an embodiment. In FIG. 15, the structure and function of the components in FIG. 15 are similar to the structure and function of like components in FIG. 14 and thus the same description as that given above with reference to FIG. 14 is omitted for conciseness.

Referring to FIG. 15, the implementation example of the first type gamma amplifier may be applied to the first gamma amplifiers GMAMP11 and GMAMP21, the implementation example of the first type gamma amplifier may be applied to a portion of the second gamma amplifiers GMAMP12 to GMA MP132 and the implementation example of the second type gamma amplifier may be applied to the remaining portion, and the implementation example of the first type gamma amplifier may be applied to a portion of a plurality of third gamma amplifiers GMA MP13 to GMAMP113 and the implementation example of the second type gamma amplifier may be applied to the remaining portion, as illustrated in FIG. 15.

In an embodiment, the implementation example of the second type gamma amplifier may be applied to the gamma amplifiers GMA MP42 to GMAMP112 that output the reference voltages VREF3 to VREF10 corresponding to an intermediate range based on a voltage level among the second gamma amplifiers GMAMP12 to GMAMP132, and the implementation example of the first type gamma amplifier may be applied to the gamma amplifiers GMAMP12 to GMAMP32 and GMAMP122, GMAMP132 that output the reference voltages VREF1, VREF2 and VREF11 corresponding to the other ranges.

As an example, the reference voltage VREF1 and the reference voltage VREF2 may fall within a low range based on the voltage level, the reference voltage VREF11 may fall within a high range based on the voltage level, and the reference voltage VREF3 to the reference voltage VREF10 may fall within a middle range between the low range and the high range. The implementation example of the first type gamma amplifier may be applied to the gamma amplifiers GMAMP12 to GMAMP32 and GMAMP122, GMAMP132 corresponding to the low range and the high range in which a stable amplification operation is more advantageous than an amplification operation consuming less power, and the implementation example of the second type gamma amplifier may be applied to the gamma amplifiers GMAMP42 to GMAMP112 corresponding to the middle range in which an amplification operation consuming less power is more advantageous than a stable amplification operation.

In an embodiment, the implementation example of the second type gamma amplifier may be applied to the gamma amplifiers GMAMP23 to GMAMP103 that output gamma voltages V21 to V101 corresponding to the middle range based on the voltage level among the third gamma amplifiers GMAMP13 to GMAMP113, and the implementation example of the first type gamma amplifier may be applied to the gamma amplifiers GMAMP13 and GMAMP113 that output gamma voltages V11 and V111 corresponding to the other ranges.

As an example, the gamma voltage V11 may fall within the low range based on the voltage level, the gamma voltage V111 may fall within the high range based on the voltage level, and the grammar voltage V21 to the grammar voltage V101 may fall within the middle range between the low range and the high range. The implementation example of the first type gamma amplifier may be applied to the gamma amplifiers GMAMP13 and GMAMP113 corresponding to the low range and the high range in which a stable amplification operation is more advantageous than an amplification operation consuming less power, and the implementation example of the second type gamma amplifier may be applied to the gamma amplifiers GMAMP23 to GMAMP103 corresponding to the middle range in which an amplification operation consuming less power is more advantageous than a stable amplification operation.

However, FIG. 15 is only an embodiment and embodiments are not limited thereto, and various implementation examples of the first and second type gamma amplifiers may be applied to the gamma amplifiers of the gamma voltage generator 700.

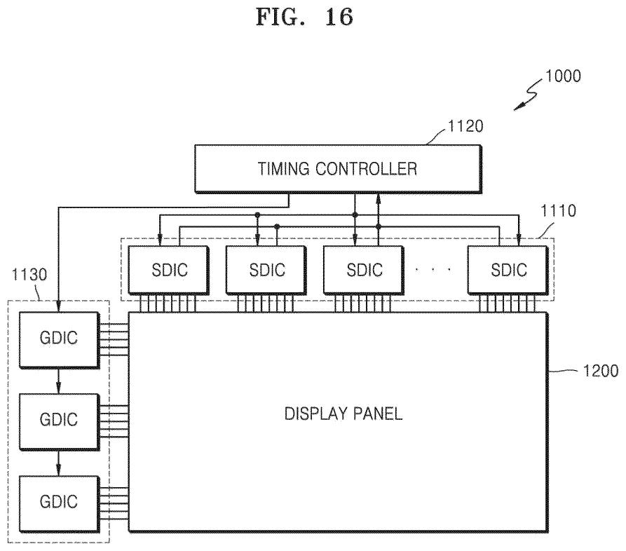

FIG. 16 illustrates an implementation example of a display device 1000 according to an embodiment. The display device 1000 of FIG. 16 is a device equipped with a medium- to large-sized display panel 1200 and may be applied to, for example, a television, a monitor, etc.

Referring to FIG. 16, the display device 1000 may include a source driver 1110, a timing controller 1120, a gate driver 1130, and the display panel 1200.

The timing controller 1120 may include one or more ICs or modules. The timing controller 1120 may communicate with a plurality of source driver ICs (SDICs) and a plurality of gate driver ICs (GDICs) through a configured interface.

The timing controller 1120 may generate control signals for controlling driving timing of the DDICs and the GDICs and provide the control signals to the DDICs and the GDICs.

The timing controller 1120 may divide image data received from an external source and provide divided image data to each of the DDICs. The timing controller 1120 may detect electrical characteristics of subpixels based on reference sensing values received from the data driver 1110 and determine compensation values for data compensation. The timing controller 1120 may perform data compensation on received image data.

The source driver 1110 may include the DDICs, and the DDICs may be mounted on a circuit film, such as a tape carrier package (TCP), a chip on film (COF), a flexible print circuit (FPC), etc. and may be attached to the display panel 1200 by a tape automatic bonding (TAB) method or may be mounted on a non-display area of the display panel 1200 by a chip on glass (COG) method.

In an embodiment, the display device 1000 may further include a plurality of gamma voltage generators that provide gamma voltages to the DDICs. The gamma voltage generators may be applied to the embodiments described above with reference to FIGS. 1 to 15. The power usage efficiency of the display device 1000 may be improved by the operation of the gamma voltage generators.

In an embodiment, the gate driver 1130 may include the GDICs, and GDICs may be mounted on a circuit film and attached to the display panel 1200 in a TAB manner or may be mounted on the non-display area of the display panel 1200 in a COG manner. In some embodiments, the gate driver 1130 may be formed directly on a lower substrate of the display panel 1200 in a gate-driver in panel (GIP) manner. The gate driver 1130 may be formed in the non-display area outside a pixel array in which subpixels SPX are formed in the display panel 1200, and may be formed using the same TFT process as that of the subpixels.

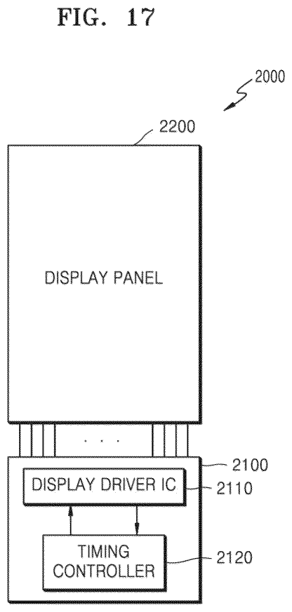

FIG. 17 illustrates an implementation example of a display device 2000 according to an embodiment. The display device 2000 of FIG. 17 may be a device having a small display panel 2200 and may be applied to mobile devices, such as smartphones, tablet PCs, etc.

Referring to FIG. 17, the display device 2000 may include a display driver 2100 and the display panel 2200. The display driver 2100 may include one or more ICs, mounted on a circuit film, such as TCP, COF, FPC, etc., and attached to the display panel 2200 in a TAB manner or mounted on a non-display area of the display panel 2200 in a COG manner.

The display driver 2100 may include a display driver IC 2110 and a timing controller 2120, and the display driver IC 2110 may include a source driver IC and a gate driver IC.

In an embodiment, the display driver IC 2110 may further include a gamma voltage generator that generates gamma voltages. The embodiments described above with reference to FIGS. 1 to 15 may be applied to the gamma voltage generator. The power usage efficiency of the display device 2000 may be improved by the operation of the gamma voltage generators.

The display driver IC 2110 may measure electrical characteristics of subpixels of the display panel 2200 in a sensing mode and provide the measured electrical characteristics of the subpixels to the timing controller 2120. The timing controller 2120 may compensate for image data based on the detected electrical characteristics of the subpixels. The timing controller 2120 may provide the compensated image data to the display driver IC 2110, and the display driver IC 2110 may drive the display panel 2200 based on the compensated image data.

While various embodiments have been particularly shown and described with reference to the drawings, it will be understood that various changes in form and details may be made therein without departing from the spirit and scope of the following claims.

What is claimed is:

1. A gamma amplifier comprising:
a first gamma amplification stage configured to amplify a first voltage;
a sample driving stage configured to amplify a second voltage that is output from the first gamma amplification stage, during a first sample period in which a first offset of the gamma amplifier is sampled;
a hold driving stage configured to amplify a third voltage that is output from the first gamma amplification stage, during a first hold period in which the first offset is canceled; and
a switching stage configured to connect the first gamma amplification stage to one stage of the hold driving stage and the sample driving stage,
wherein the sample driving stage consumes less power than the hold driving stage.

2. The gamma amplifier of claim 1, wherein:
the sample driving stage includes a first transistor,
the hold driving stage includes a second transistor, and
a width of the first transistor is narrower than a width of the second transistor.

3. The gamma amplifier of claim 1, wherein:
the sample driving stage includes a first transistor,
the hold driving stage includes a second transistor, and
a gate voltage applied to the first transistor is different from a gate voltage applied to the second transistor.

4. The gamma amplifier of claim 1, wherein:
the first gamma amplification stage includes a plurality of first transistors,
the sample driving stage includes a plurality of second transistors,
the hold driving stage includes a plurality of third transistors,
the plurality of first transistors have a first correlation with the first offset, the first correlation being higher than a first threshold, and
the plurality of second transistors and the plurality of third transistors have a second correlation with the first offset, the second correlation being lower than a second threshold.

5. The gamma amplifier of claim 1, further comprising a capacitor that is charged by the first offset during the first sample period and discharged during the first hold period.

6. The gamma amplifier of claim 1, further comprising:
an output terminal,
wherein an output node of the sample driving stage is disconnected from the output terminal, and
an output node of the hold driving stage is connected to the output terminal.

7. The gamma amplifier of claim 1, wherein the first offset that is sampled during the first sample period is based on a difference between the second voltage that is amplified by the sample driving stage and the first voltage.

8. The gamma amplifier of claim 1, wherein:
the first voltage is input to a positive input terminal of the first gamma amplification stage, and
in the first hold period, a voltage corresponding to the first offset is applied to a negative input terminal of the first gamma amplification stage.

9. The gamma amplifier of claim 1, further comprising:
a second gamma amplification stage configured to amplify a fourth voltage,
wherein the sample driving stage is further configured to amplify a fifth voltage that is output from the second gamma amplification stage, during a second sample period in which a second offset of the gamma amplifier is sampled,
the hold driving stage is further configured to amplify a sixth voltage that is output from the second gamma amplification stage, during a second hold period in which the second offset is canceled, and
the switching stage is further configured to connect the second gamma amplification stage to a selected one of the hold driving stage and the sample driving stage.

10. The gamma amplifier of claim 9, wherein:
the first sample period corresponds to the second hold period, and
the first hold period corresponds to the second sample period.

11. A gamma amplifier comprising:
a first gamma amplification stage configured to amplify a first voltage;
a hold driving stage configured to amplify a second voltage that is output from the first gamma amplification stage, during a first hold period in which a first offset of the gamma amplifier is canceled; and
a switching stage configured to connect the first gamma amplification stage to the hold driving stage in the first hold period and to connect the first gamma amplification stage to a first sampling node during a first sample period in which the first offset is sampled.

12. The gamma amplifier of claim 11, wherein power consumed by the first gamma amplification stage during the first sample period is less than a combined power consumed by the first gamma amplification stage and the hold driving stage during the first hold period.

13. The gamma amplifier of claim 11, wherein the first offset that is sampled during the first sample period is based on a difference between a third voltage of the first sampling node and the first voltage.

14. The gamma amplifier of claim 11, further comprising:
an output terminal,
wherein the first sampling node is disconnected from the output terminal, and
an output node of the hold driving stage is connected to the output terminal.

15. The gamma amplifier of claim 11, wherein:
during the first sample period, a voltage of the first sampling node is input to a positive input terminal of the first gamma amplification stage, and the first voltage is input to a negative input terminal of the first gamma amplification stage, and
during the first hold period, the first voltage is input to the positive input terminal of the first gamma amplification stage, and a voltage of an output node of the hold driving stage is input to the negative input terminal of the first gamma amplification stage.

16. The gamma amplifier of claim 11, further comprising:
a second gamma amplification stage configured to amplify a third voltage,
wherein the hold driving stage is further configured to amplify a fourth voltage that is output from the second gamma amplification stage, during a second hold period in which a second offset of the gamma amplifier is canceled, and
wherein the switching stage is further configured to connect the second gamma amplification stage to the hold driving stage during the second hold period and to connect the second gamma amplification stage to a second sampling node during a second sample period in which the second offset is sampled.

17. A display driver integrated circuit comprising:
a gate driver integrated circuit configured to control a plurality of gate lines connected to a display panel;
a gamma voltage generator configured to generate a plurality of gamma voltages; and
a source driver integrated circuit configured to control a plurality of data lines connected to the display panel, based on the plurality of gamma voltages and based on data,
wherein the gamma voltage generator includes a plurality of gamma amplifiers configured to sample an offset on a low power basis during a sample period and to generate a gamma voltage, based on the offset sampled during the sample period, during a hold period.

18. The display driver integrated circuit of claim 17, wherein:
one of the plurality of gamma amplifiers includes:
a gamma amplification stage which performs a primary amplification operation;
a sample driving stage connected to the gamma amplification stage to perform a secondary amplification operation during the sample period in which the offset is sampled;
a hold driving stage connected to the gamma amplification stage during the hold period in which the offset is canceled and configured to perform the secondary amplification operation; and
a switching stage configured to connect one stage of the sample driving stage and the hold driving stage to the gamma amplification stage.

19. The display driver integrated circuit of claim 17, wherein:
one of the plurality of gamma amplifiers includes:
a gamma amplification stage configured to perform a primary amplification operation;
a hold driving stage connected to the gamma amplification stage and configured to perform a secondary amplification operation during the hold period in which the offset is canceled; and
a switching stage configured to connect the gamma amplification stage to the hold driving stage during the hold period and to connect the gamma amplification stage to a sampling node during the sample period in which the offset is sampled.

20. The display driver integrated circuit of claim 17, wherein:
the plurality of gamma amplifiers include:
a plurality of first gamma amplifiers including a sample driving stage configured to be used in the sample period; and
a plurality of second gamma amplifiers in which the sample driving stage is omitted.
